(19) United States
(12) Patent Application Publication
(10) Pub. No.: US 2024/0321988 A1
(43) Pub. Date: Sep. 26, 2024

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Kuo-Cheng CHIANG, Zhubei City (TW); Guan-Lin CHEN, Baoshan Township (TW); Yu-Xuan HUANG, Hsinchu (TW); Jin CAI, Hsinchu City (TW); Chih-Hao WANG, Baoshan Township (TW)

(21) Appl. No.: 18/188,020

(22) Filed: Mar. 22, 2023

(51) Int. Cl. H01L 29/423; H01L 21/8234; H01L 27/088; H01L 29/06; H01L 29/66; H01L 29/775; H01L 29/786

(52) U.S. Cl. CPC H01L 29/42392; H01L 21/823412; H01L 21/823418; H01L 27/088; H01L 29/0673; H01L 29/66439; H01L 29/775; H01L 29/78621; H01L 29/78696

(57) ABSTRACT

A semiconductor structure includes a channel layer, a top source/drain feature, a bottom source/drain feature, a gate structure, and a supporting structure. The channel layer extends in a Z-direction. The top source/drain feature is over and electrically connected to the channel layer. The bottom source/drain feature is under and electrically connected to the channel layer. The gate structure laterally wraps around the channel layer. The supporting structure extends in an X-direction. The supporting structure is in contact with the channel layer, the top source/drain feature, and the bottom source/drain feature in a Y-direction.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) transistors have been incorporated into memory devices (including, for example, static random-access memory, or SRAM, cells) and core devices (including, for example, standard logic, or STD, cells) to reduce chip footprint while maintaining reasonable processing margins.

However, although existing technologies for GAA transistors have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of a portion of a workpiece at a fabrication stage, in accordance with some embodiments of the present disclosure.

FIGS. 1B-1, 1C-1, 1D-1, 1E-1, 1F-1, 1G-1, 1H-1, 11-1, 1J-1, 1K-1, 1L-1, 1M-1, 1N-1, 10-1, 1P-1, 1Q-1, 1R-1, 1S-1, 1T-1, 1U-1, and 1V-1 are top views of the portion of the workpiece at various fabrication stages, in accordance with some embodiments of the present disclosure.

FIGS. 1B-2, 1C-2, 1D-2, 1E-2, 1F-2, 1G-2, 1H-2, 11-2, 1J-2, 1K-2, 1L-2, 1M-2, 1N-2, 10-2, 1P-2, 1Q-2, 1R-2, 1S-2, 1T-2, 1U-2, and 1V-2 are X-Z cross-sectional views of the portion of the workpiece at various fabrication stages along lines A-A′ of FIGS. 1A and 1B-1 to 1V-1, in accordance with some embodiments of the present disclosure.

FIGS. 1B-3, 1C-3, 1D-3, 1E-3, 1F-3, 1G-3, 1H-3, 11-3, 1J-3, 1K-3, 1L-3, 1M-3, 1N-3, 10-3, 1P-3, 1Q-3, 1R-3, 1S-3, 1T-3, 1U-3, and 1V-3 are Y-Z cross-sectional views of the portion of the workpiece at various fabrication stages along lines B-B′ of FIGS. 1A and 1B-1 to 1V-1, in accordance with some embodiments of the present disclosure.

FIGS. 1W-1, 1X-1, 1Y-1, and 1Z-1 are X-Z cross-sectional views of the portion of the workpiece at various fabrication stages along lines A-A′ of FIGS. 1A and 1B-1 to 1V-1, in accordance with some embodiments of the present disclosure.

FIGS. 1W-2, 1X-2, 1Y-2, and 1Z-2 are Y-Z cross-sectional views of the portion of the workpiece at various fabrication stages along lines B-B′ of FIGS. 1A and 1B-1 to 1V-1, in accordance with some embodiments of the present disclosure.

FIG. 1Z-3 is an X-Y cross-sectional view of the portion of the workpiece at a fabrication stage along a line C-C′ of FIG. 1Z-2, in accordance with some embodiments of the present disclosure.

FIG. 2 is a Y-Z cross-sectional view of the portion of the workpiece at a fabrication stage corresponding to FIG. 1Z-2 and along lines B-B′ of FIGS. 1A and 1B-1 to 1V-1, in accordance with some embodiments of the present disclosure.

FIG. 3 is a Y-Z cross-sectional view of the portion of the workpiece at a fabrication stage corresponding to FIG. 1Z-2 and along lines B-B′ of FIGS. 1A and 1B-1 to 1V-1, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional vertical gate-all-around (VGAA) transistors, in memory (e.g., SRAM) and/or standard logic cells of an integrated circuit (IC) structure. Generally, a VGAA transistor may include a vertically extending sheet (e.g., a nanosheet), wire (e.g., a nanowire), or rod (e.g., a nanorod) in a channel region of the transistor, thereby allowing better gate control, lowered leakage current, and improved scaling capability for various IC applications. While existing technologies for fabricating VGAA transistors have been generally adequate for their intended applications, they have not been entirely satisfactory in all aspects.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures including VGAA transistors with a supporting structure supporting channel layers of the VGAA transistors, thereby preventing collapse of the VGAA transistors during the formation of the VGAA transistors. The details of the structure and manufacturing methods of the present disclosure are described below in conjunction with the accompanying drawings, which illustrate the process of making VGAA transistors, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise excepted.

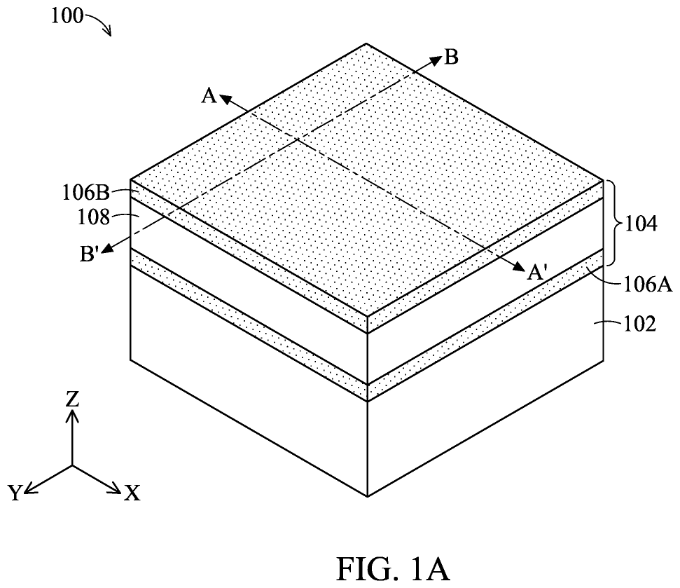

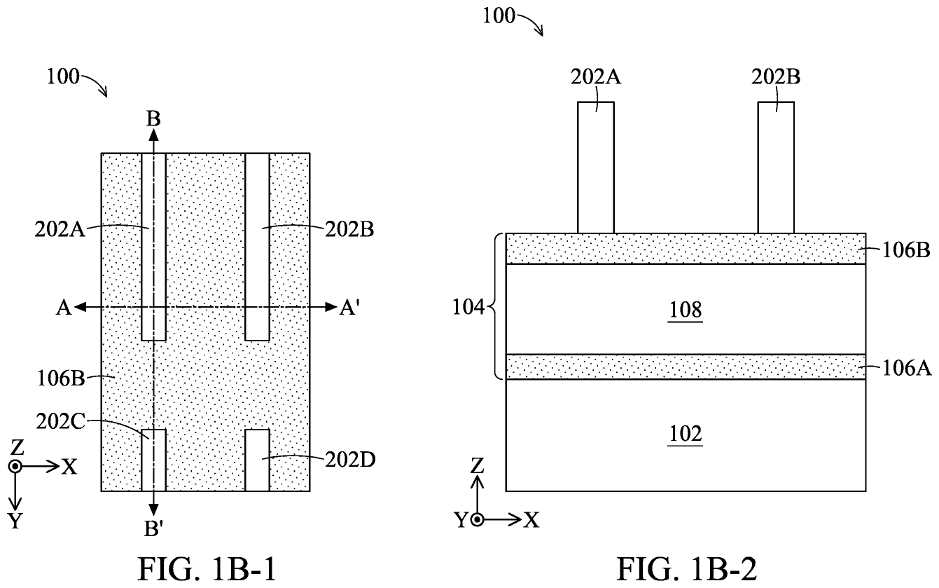

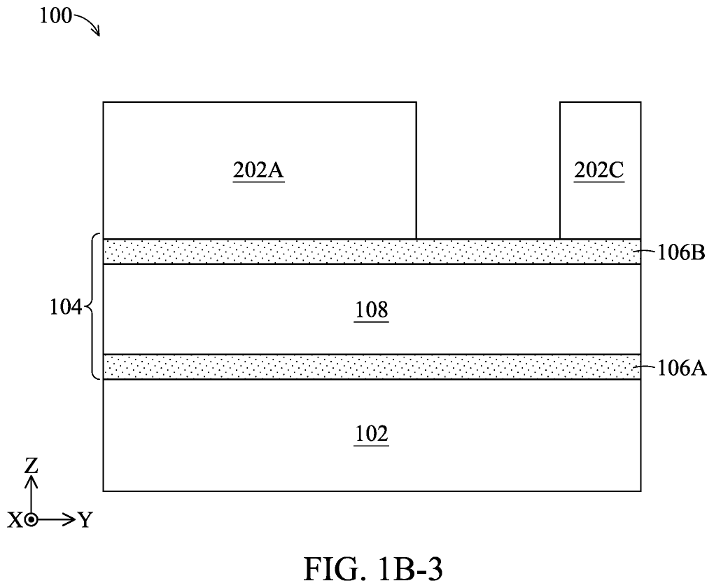

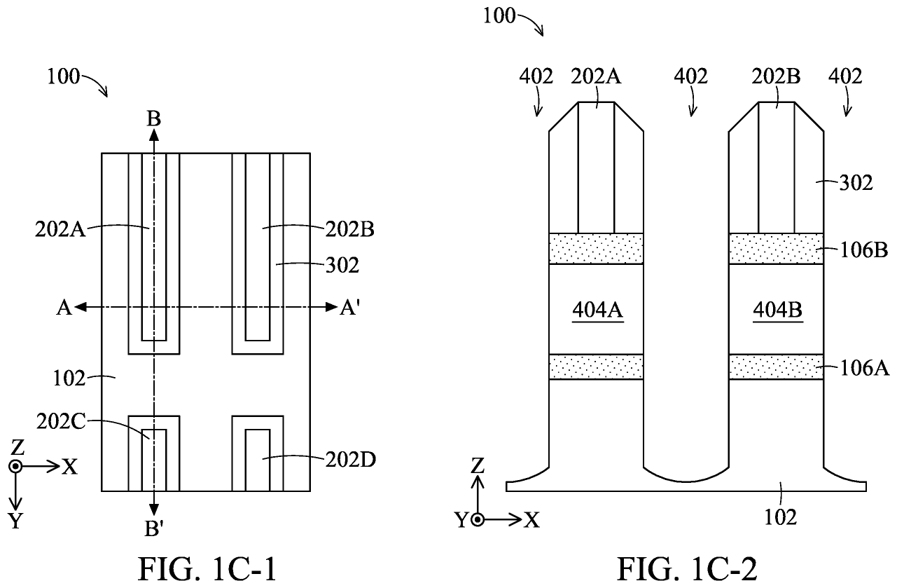

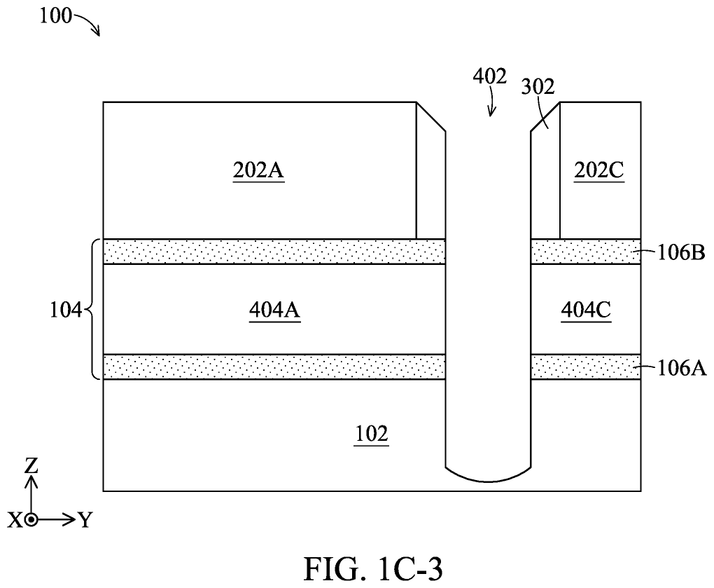

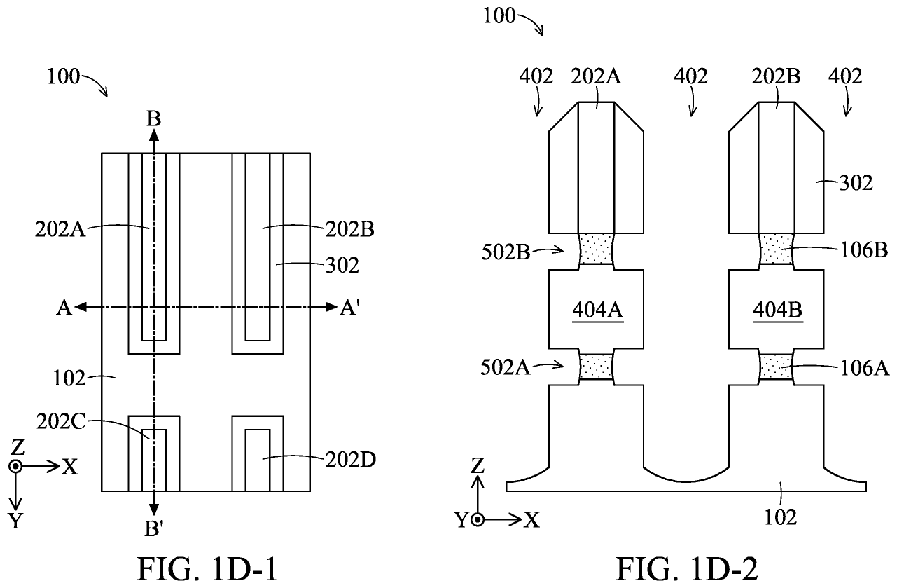

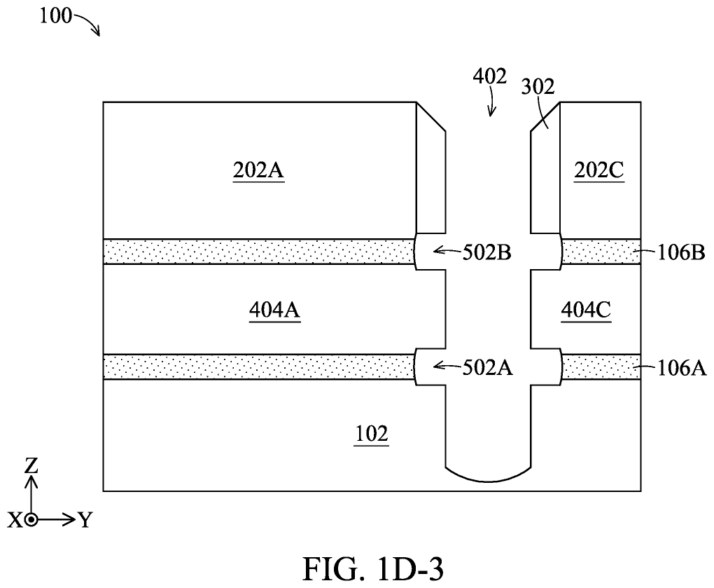

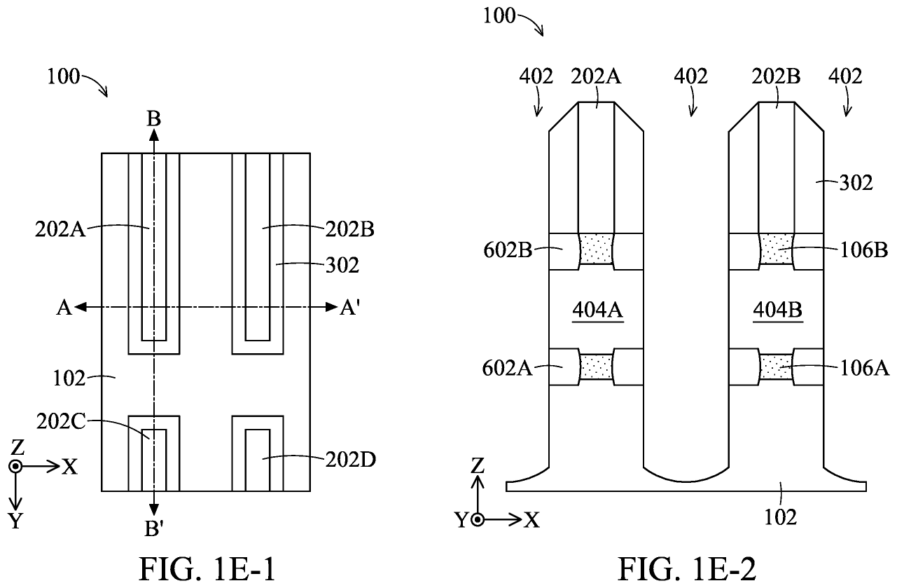

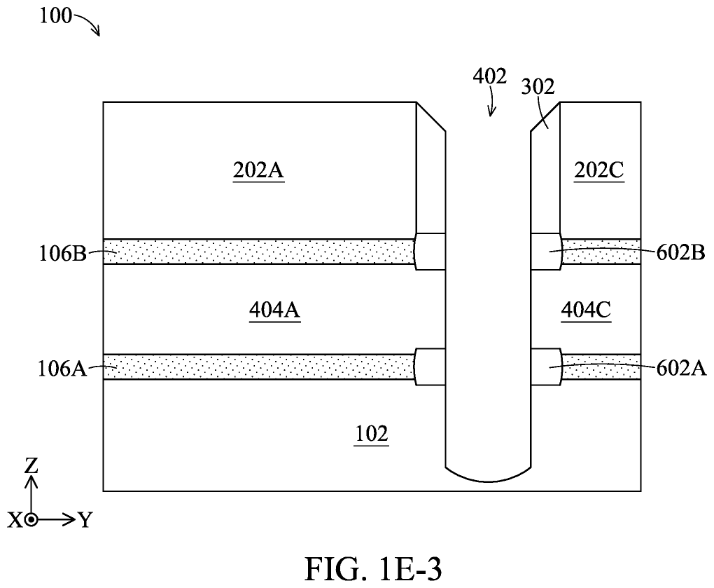

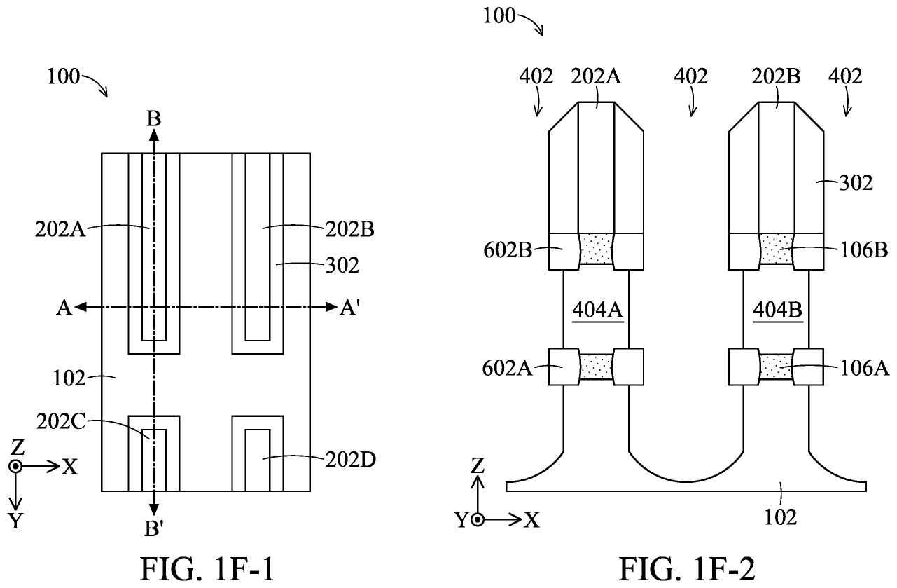

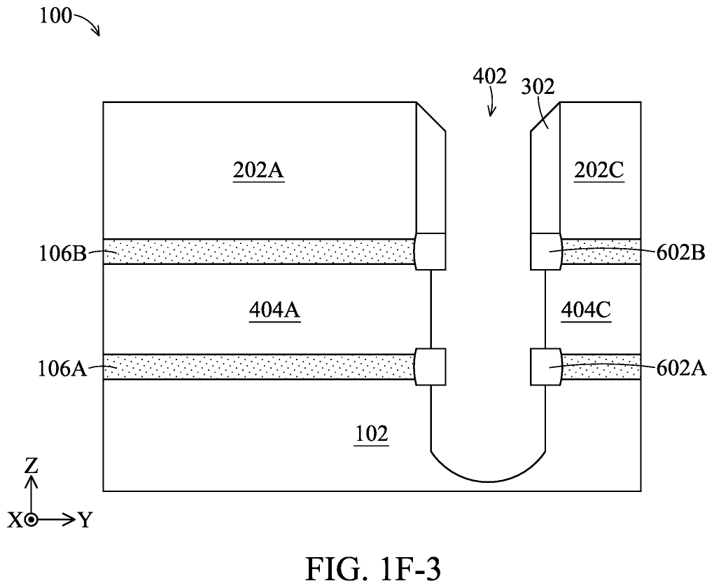

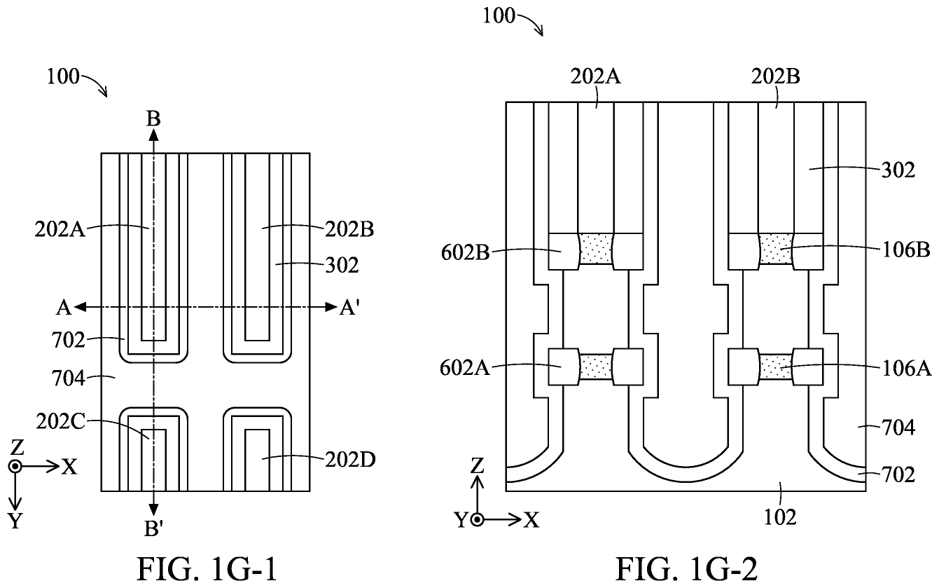

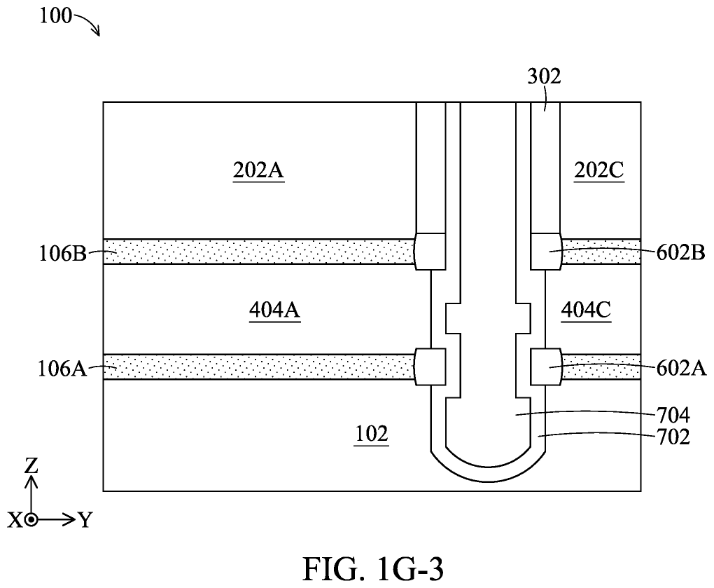

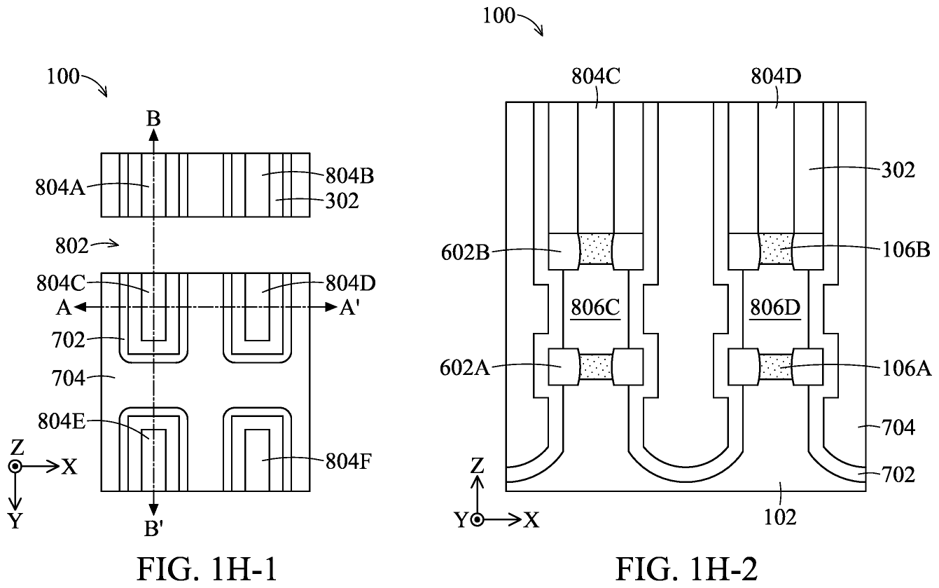

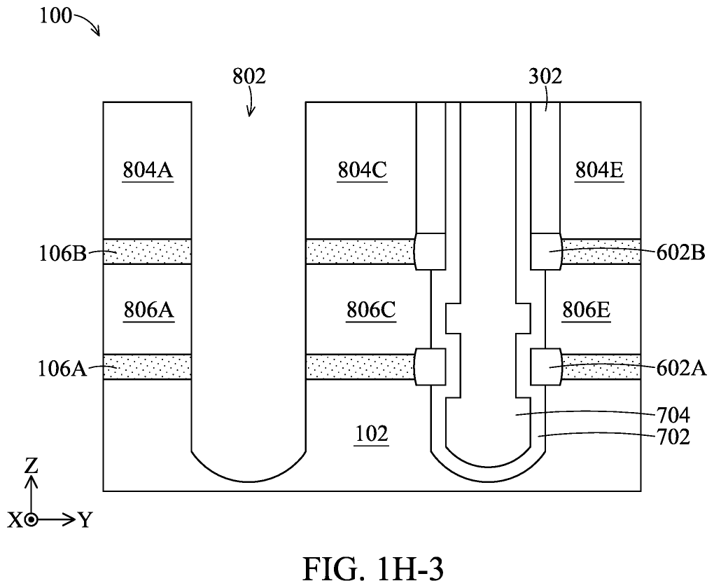

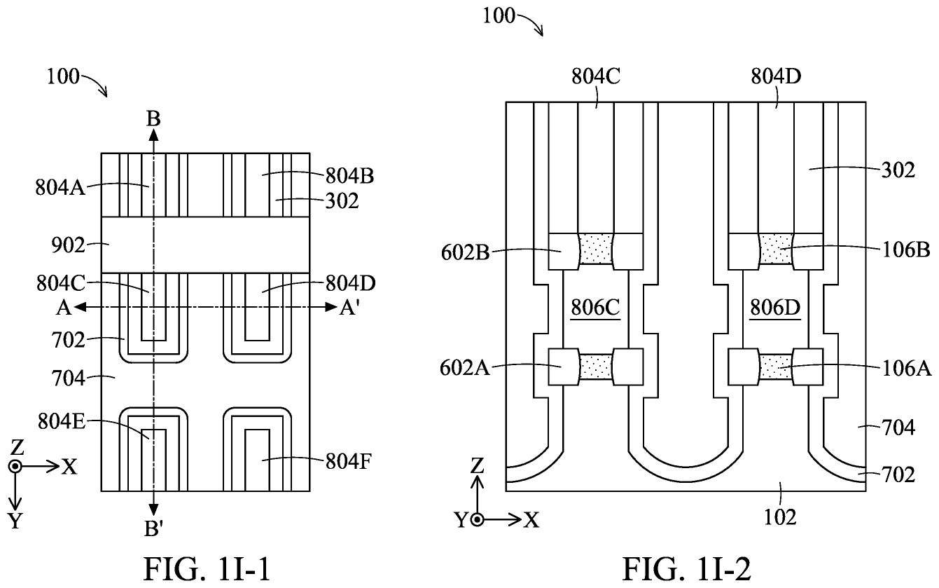

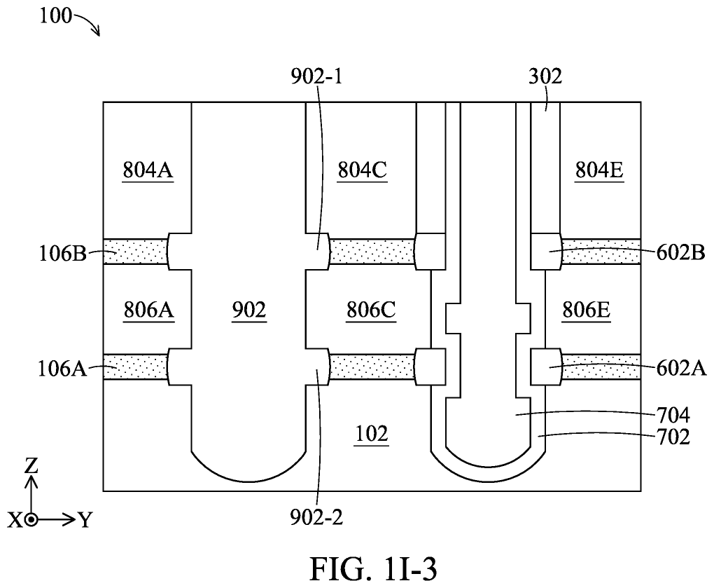

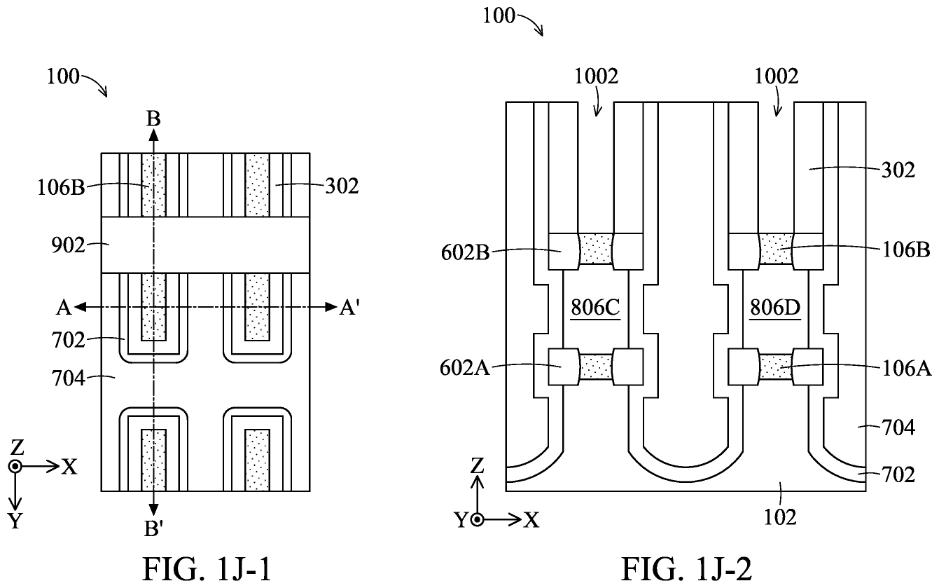

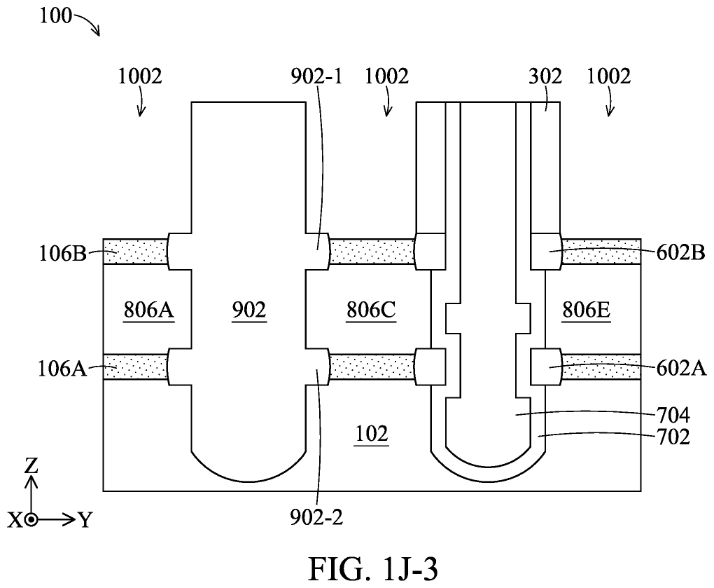

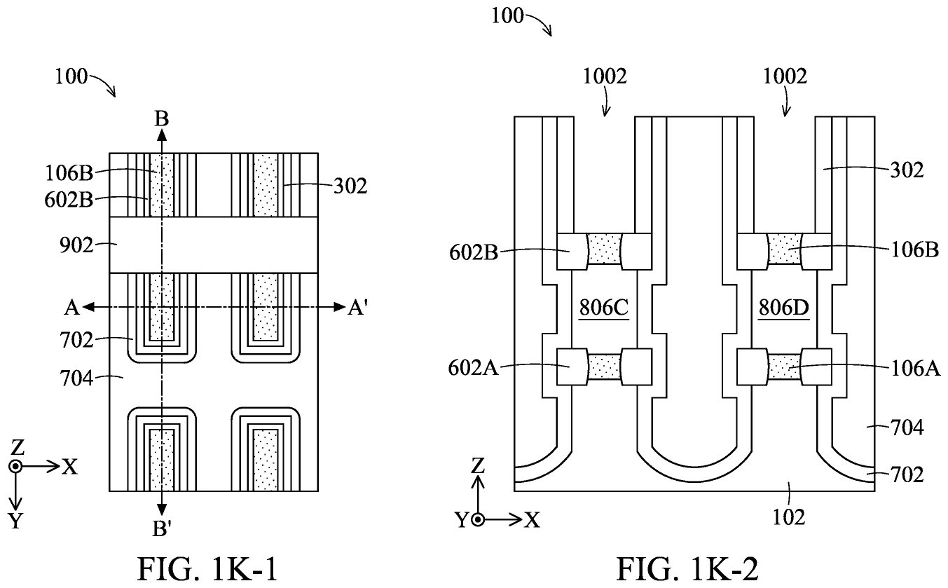

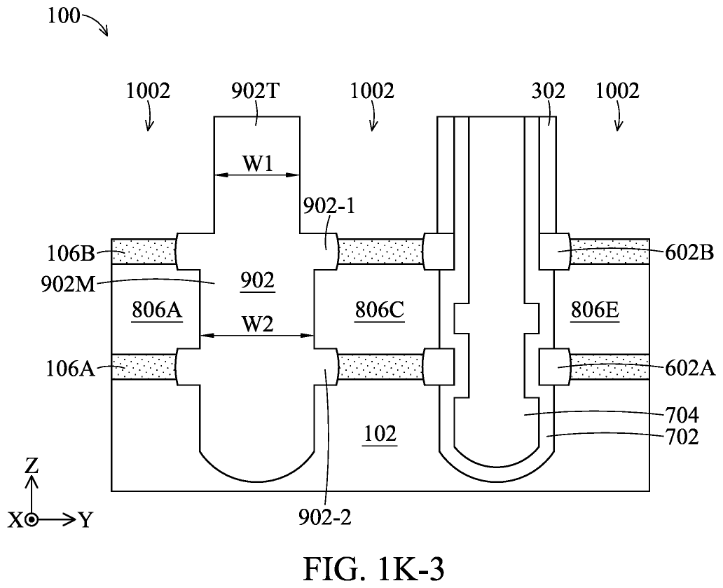

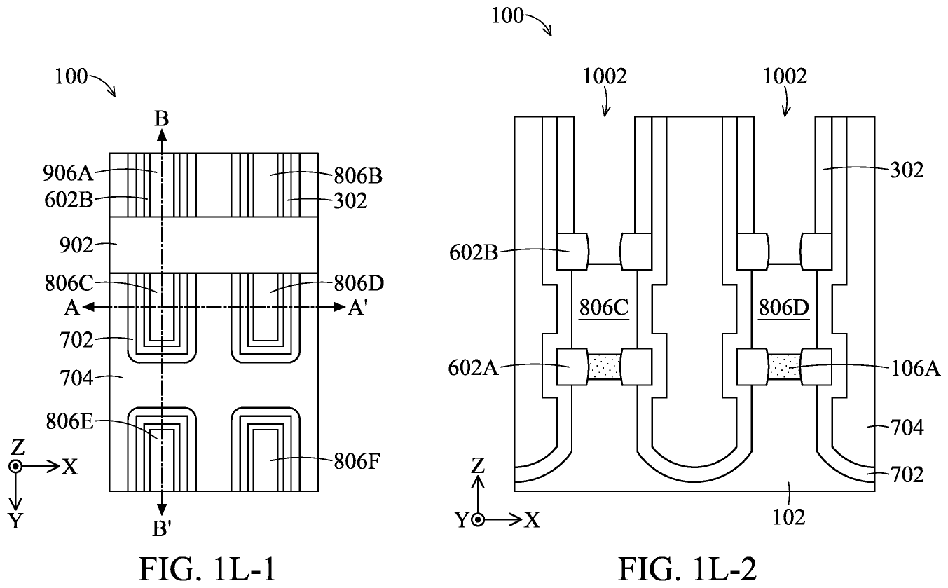

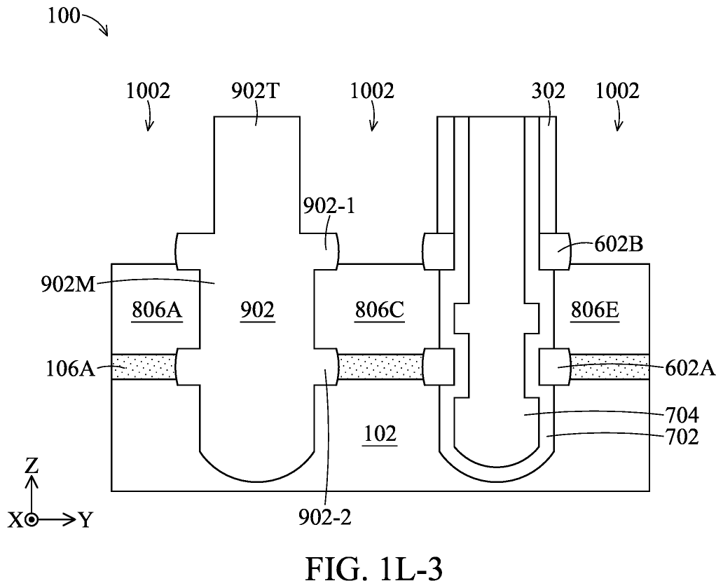

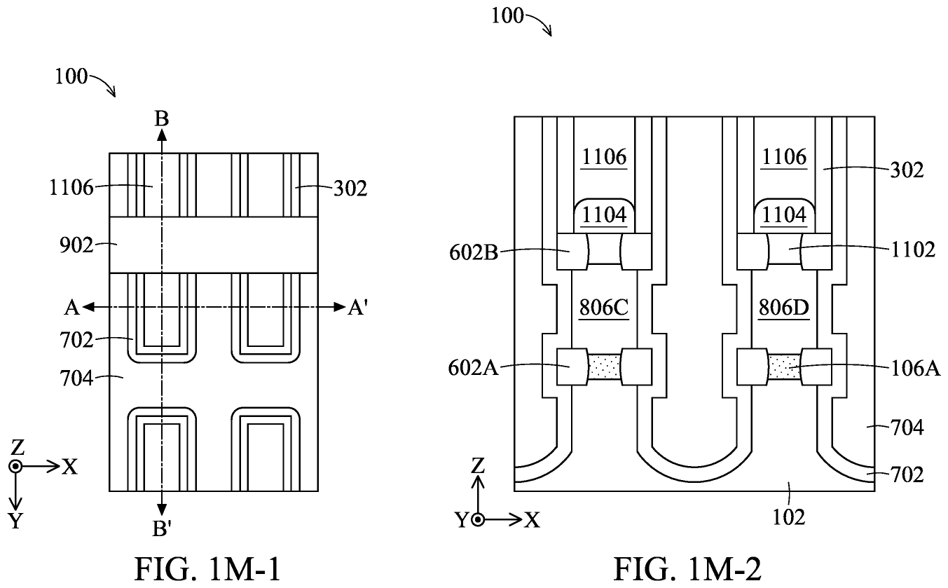

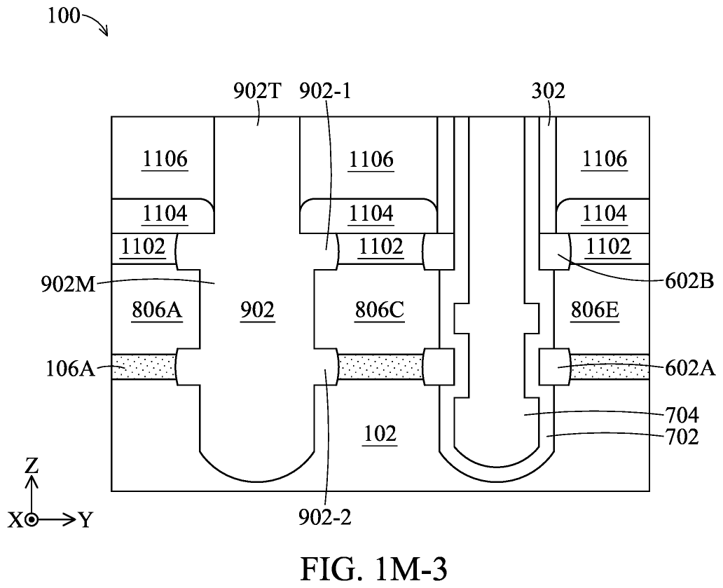

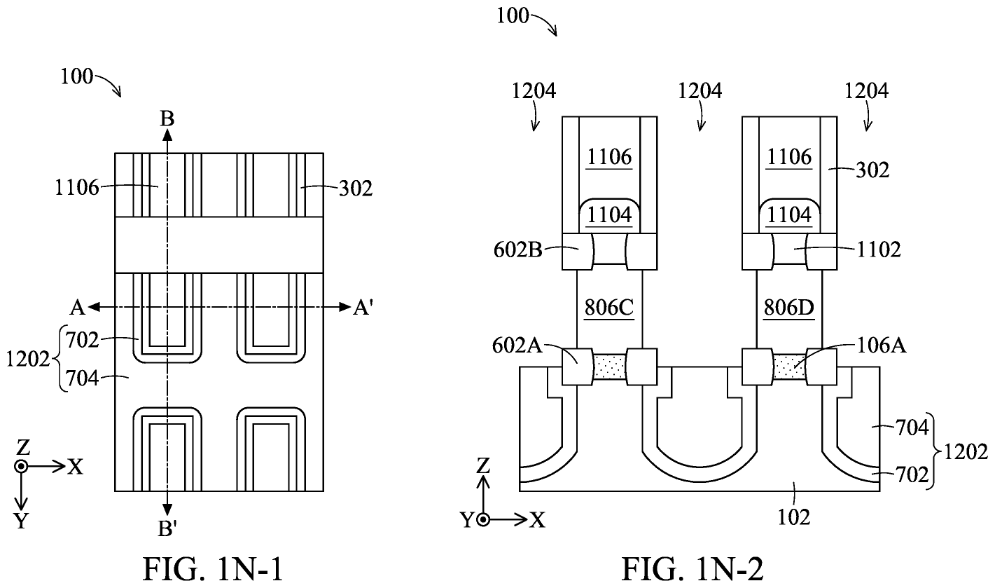

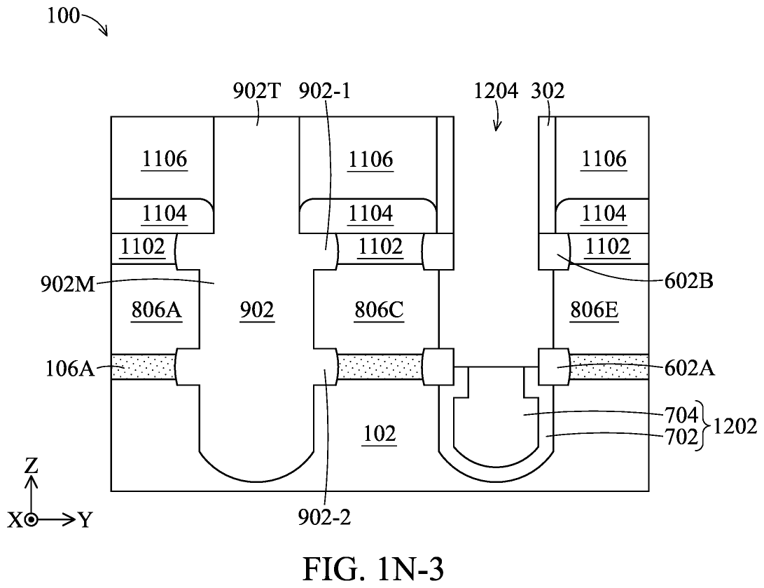

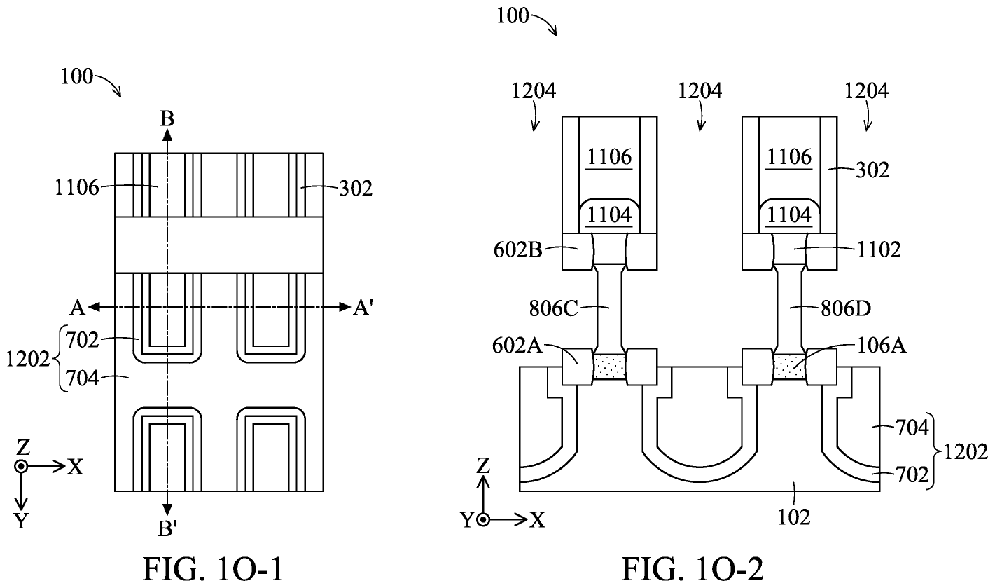

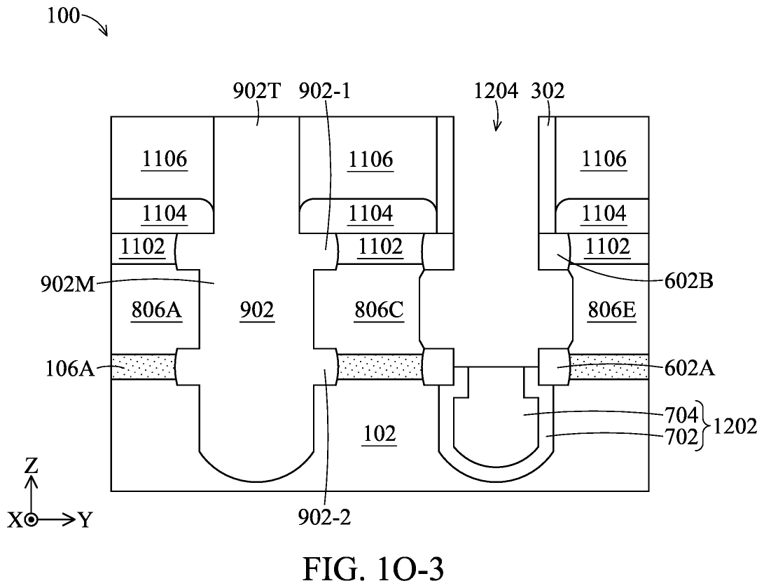

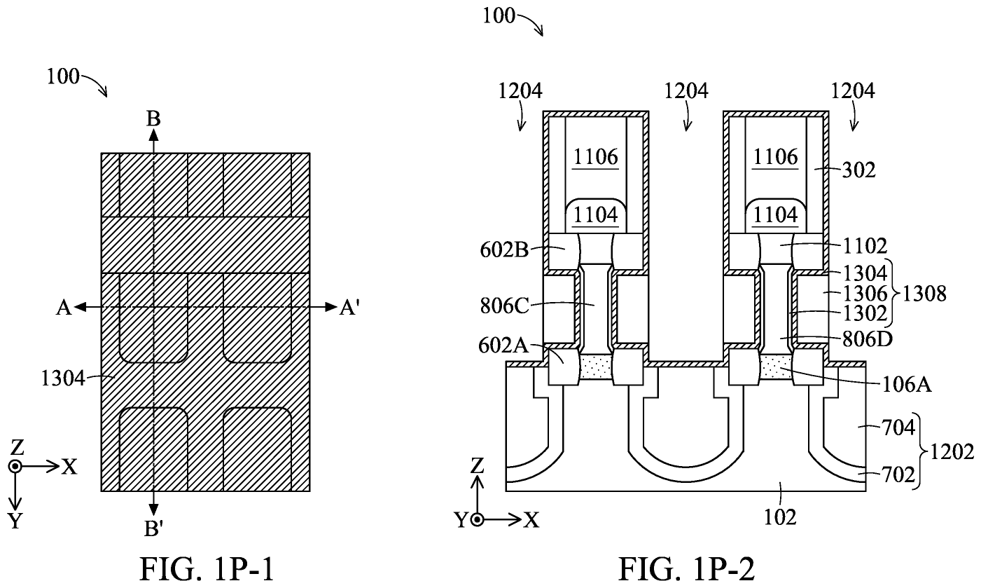

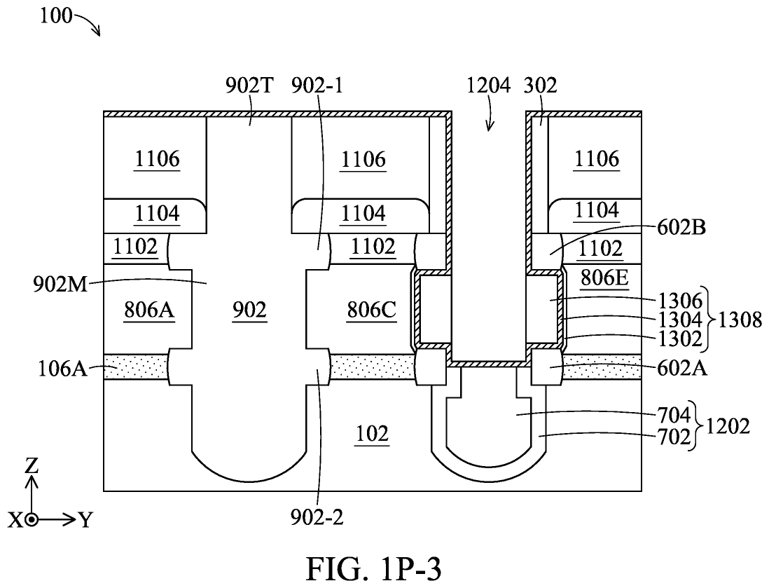

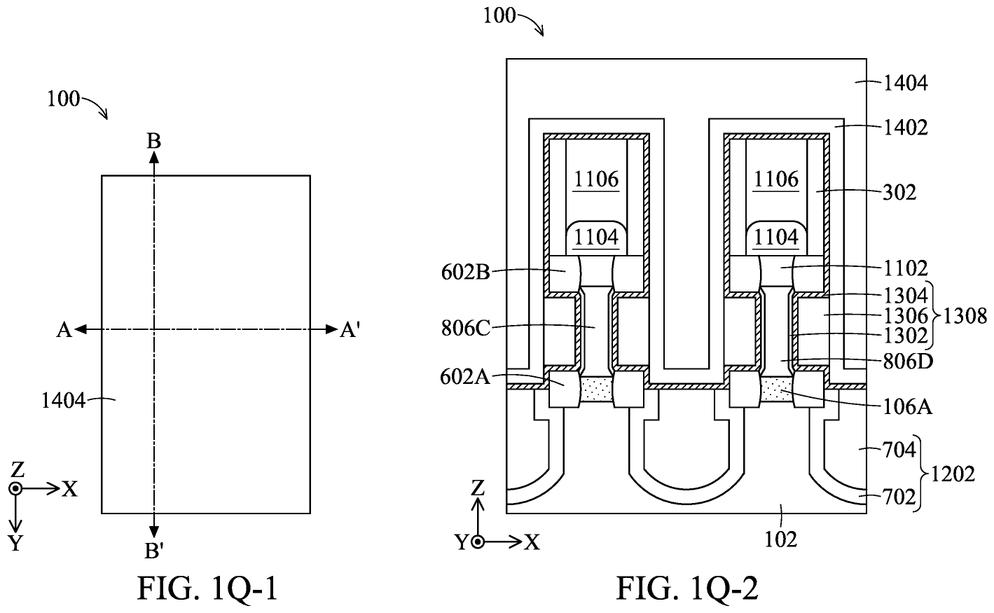

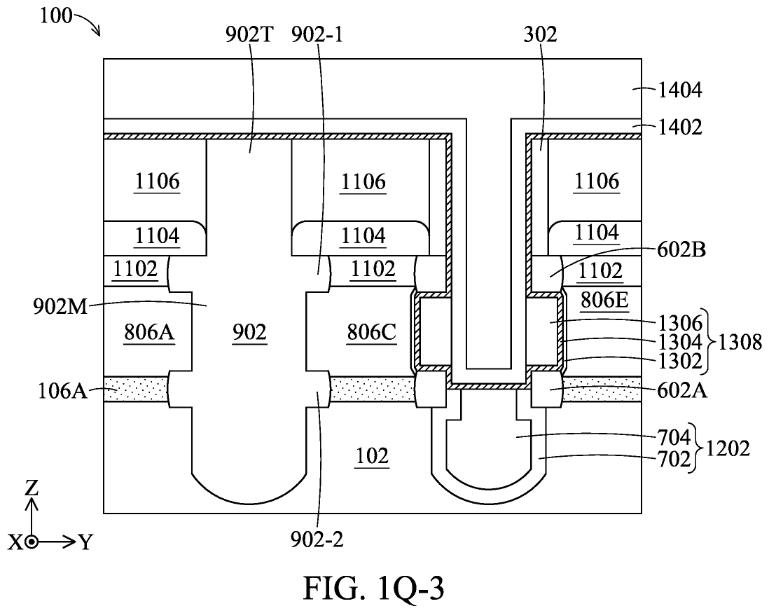

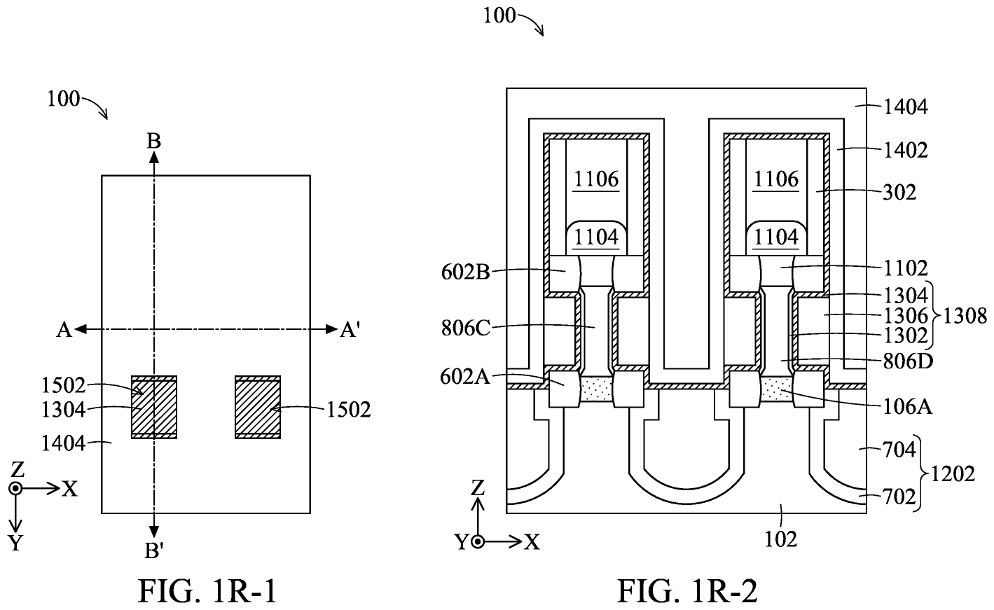

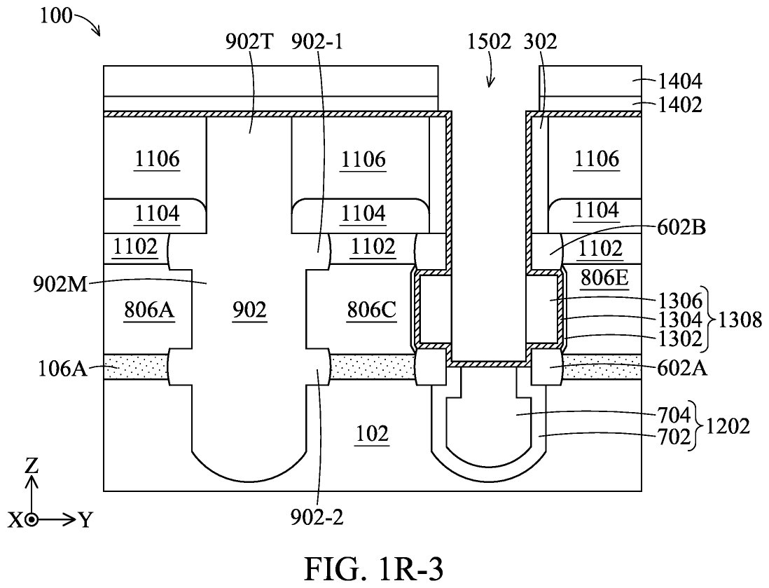

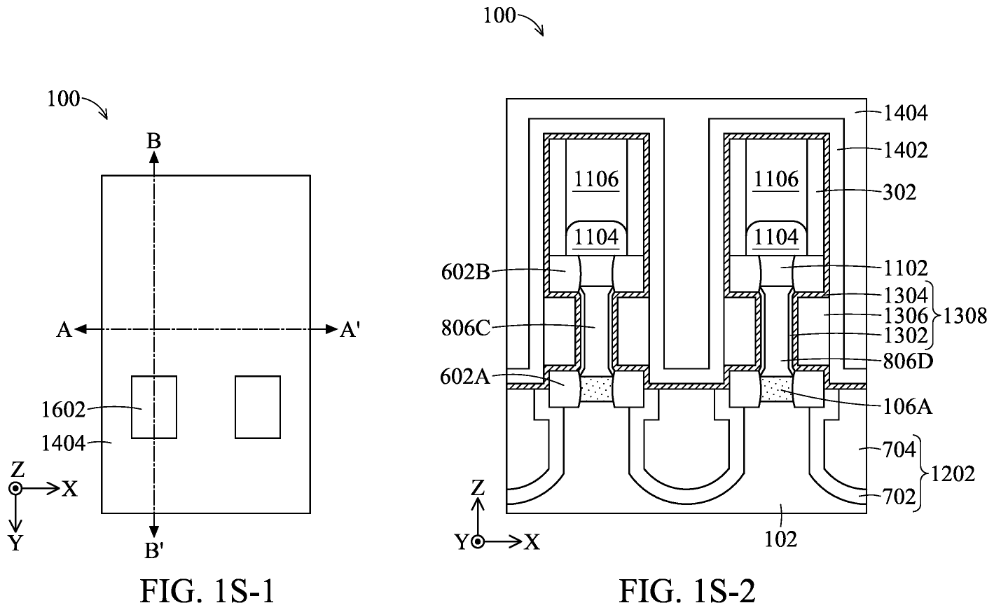

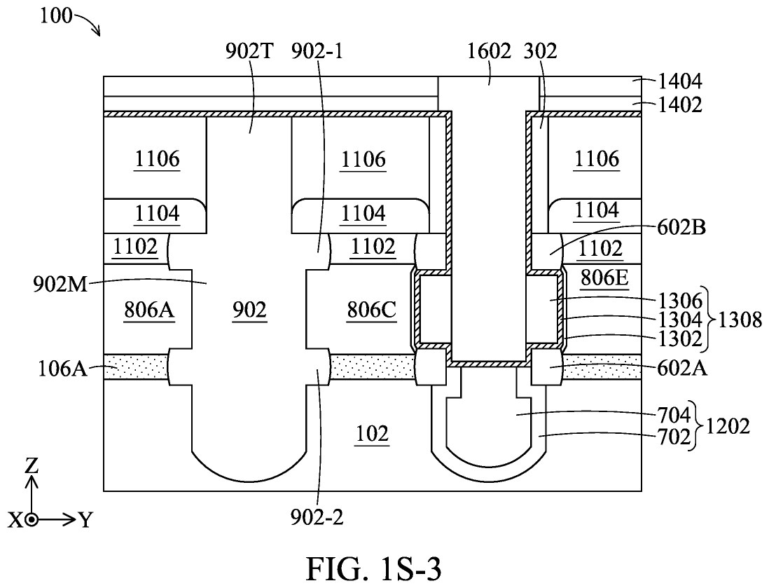

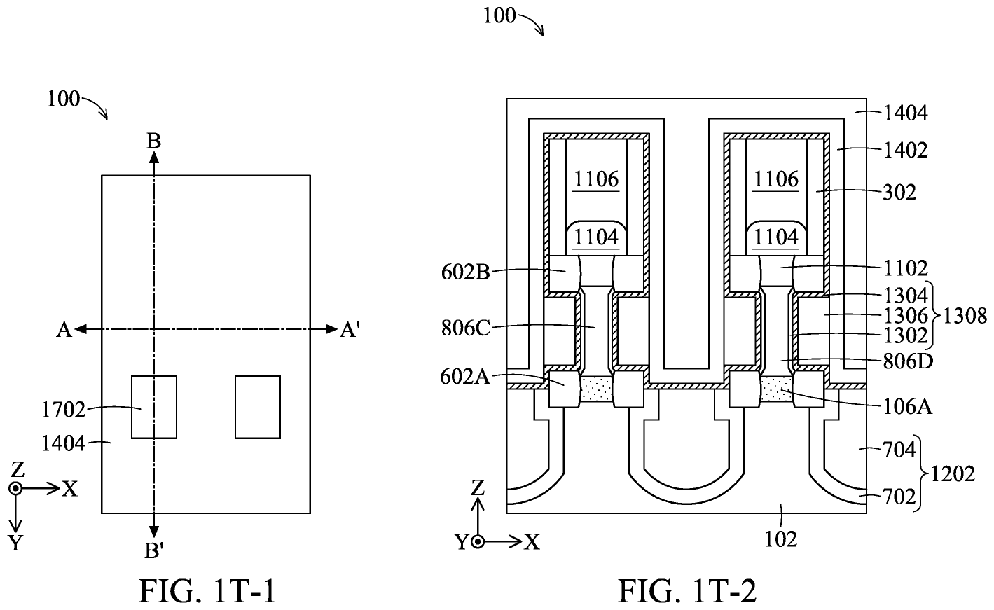

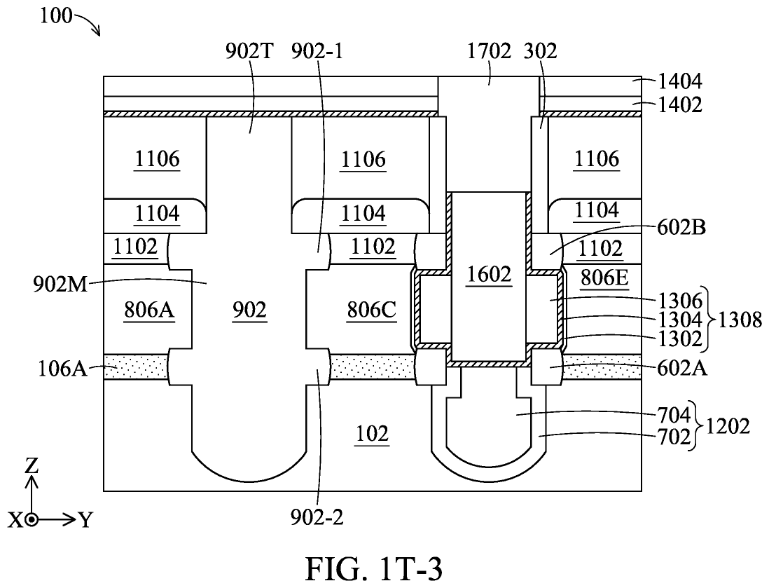

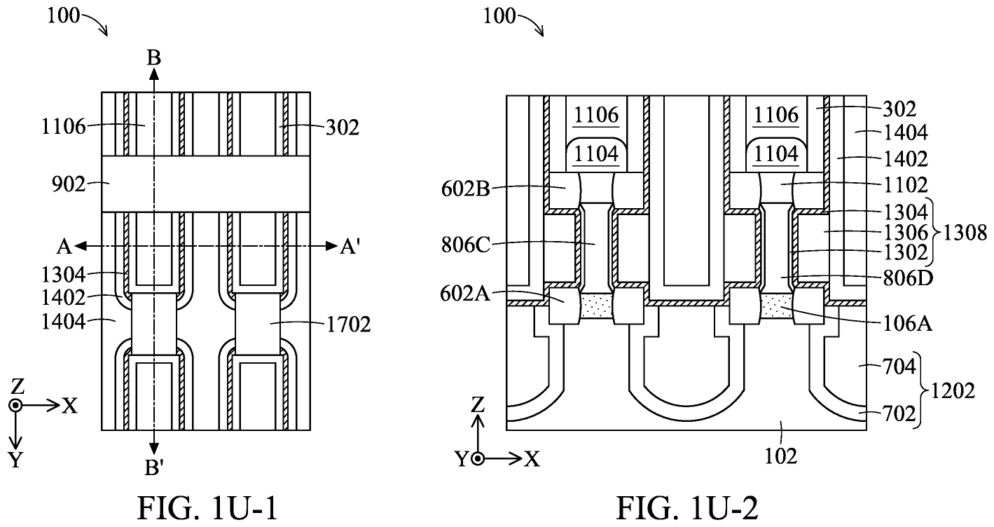

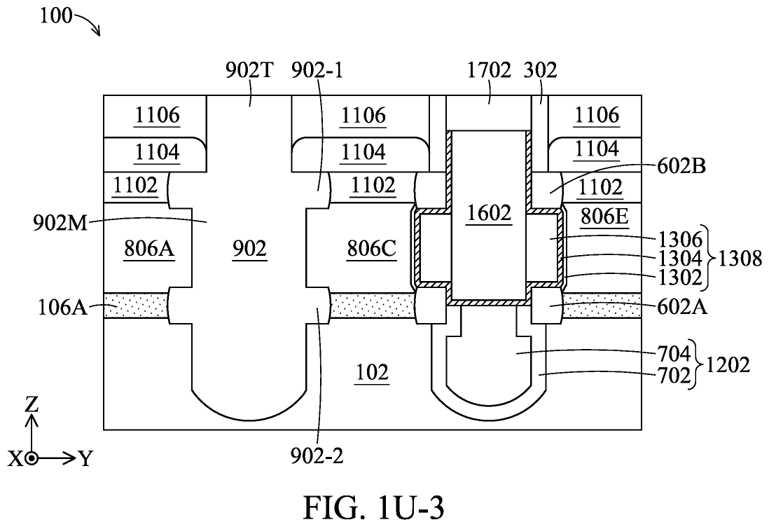

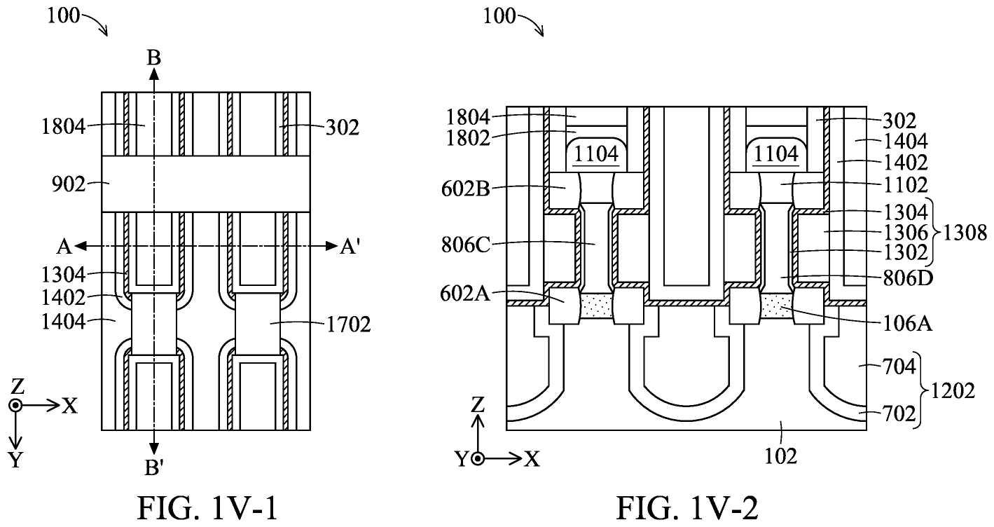

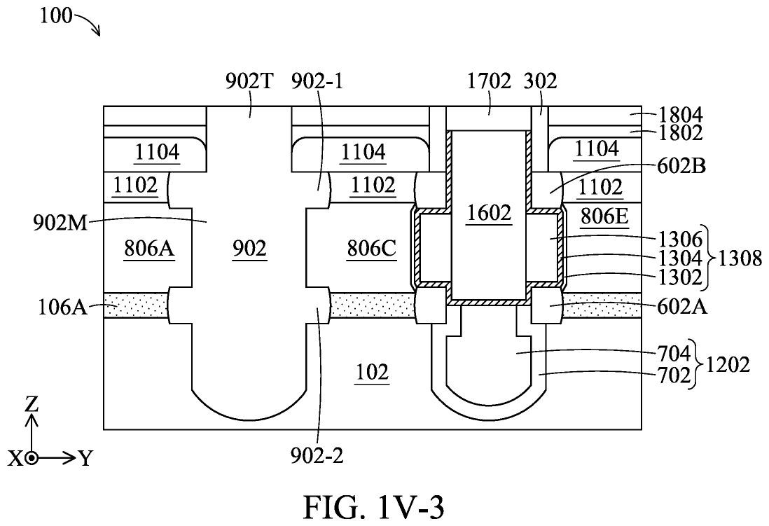

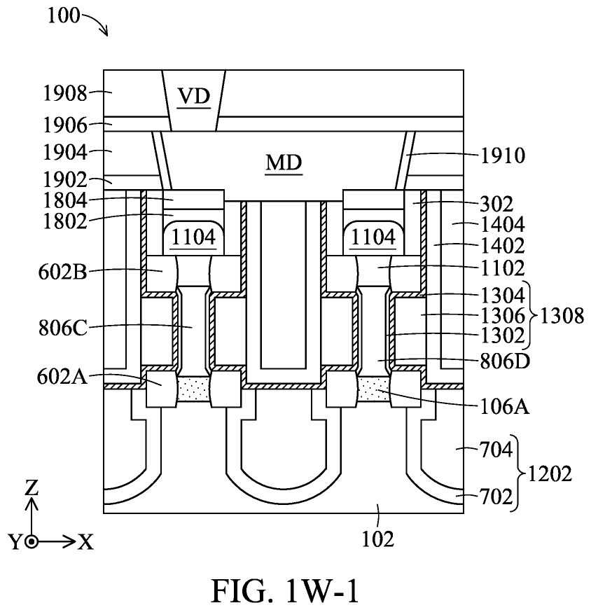

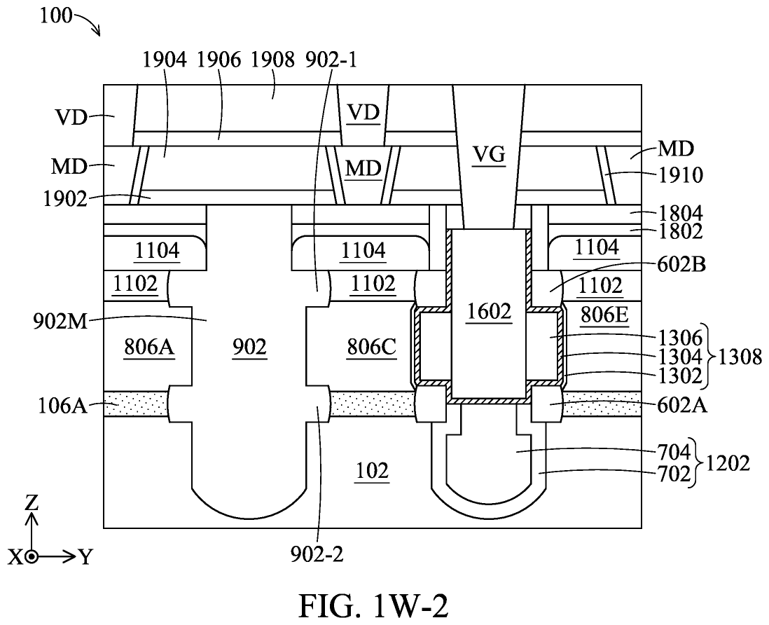

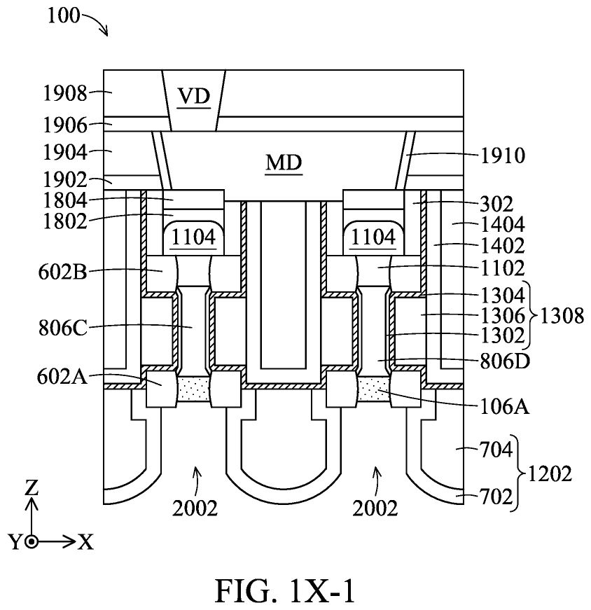

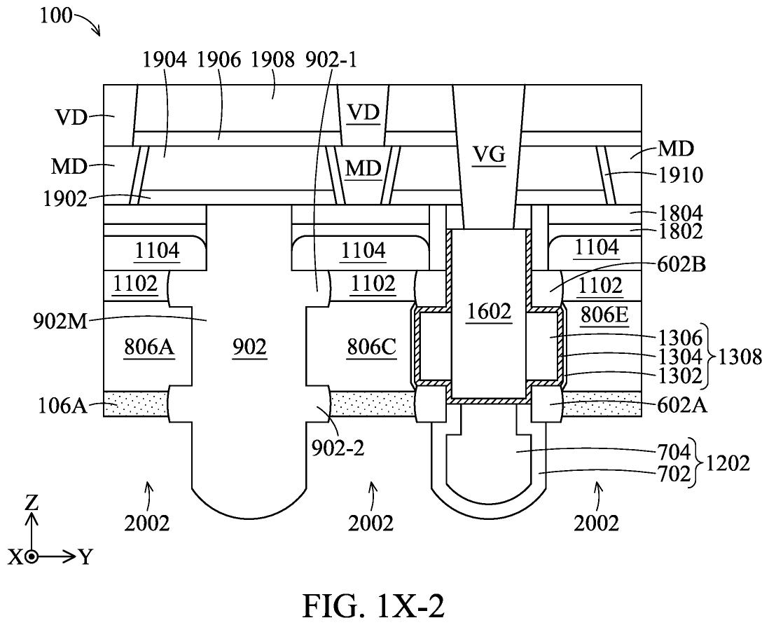

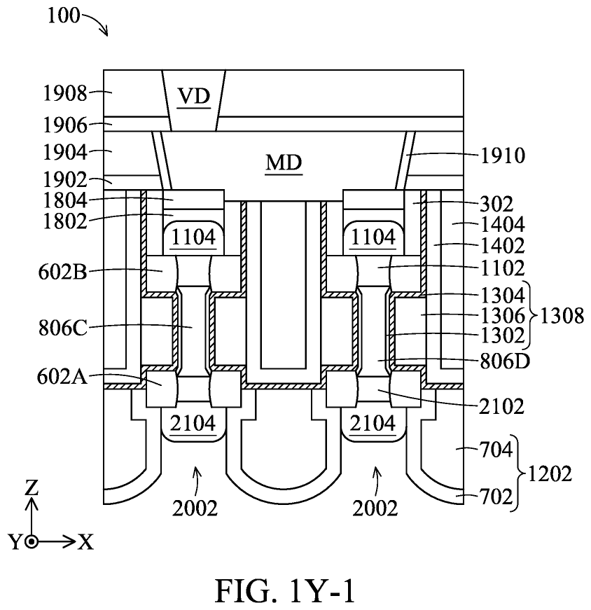

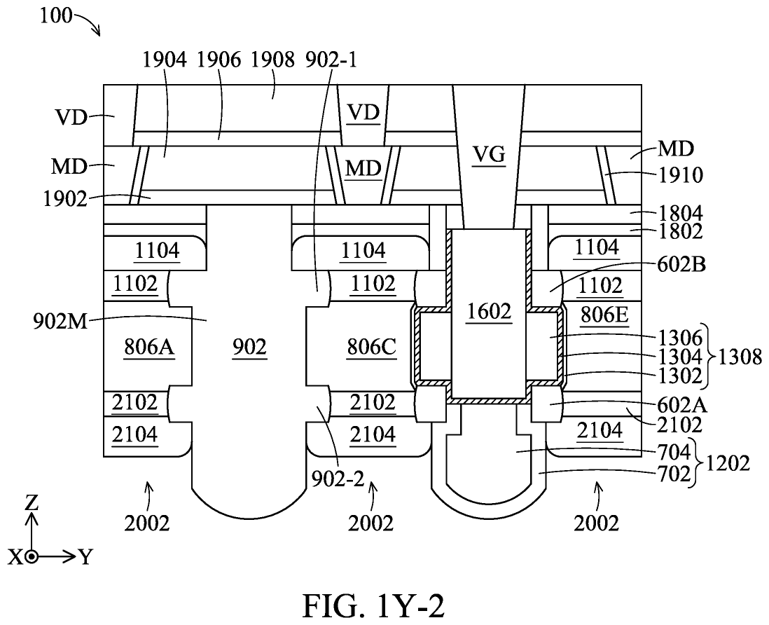

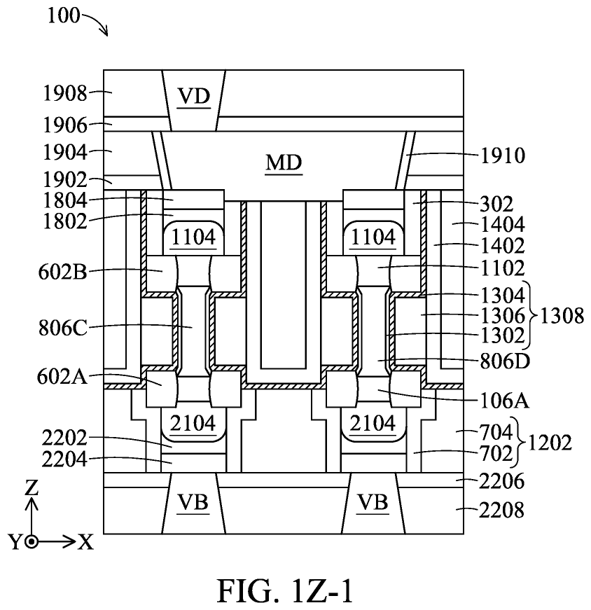

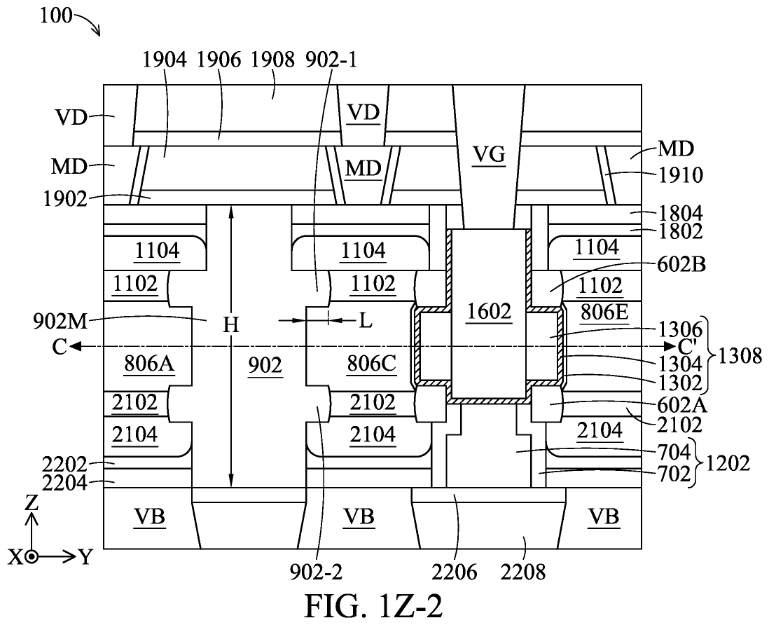

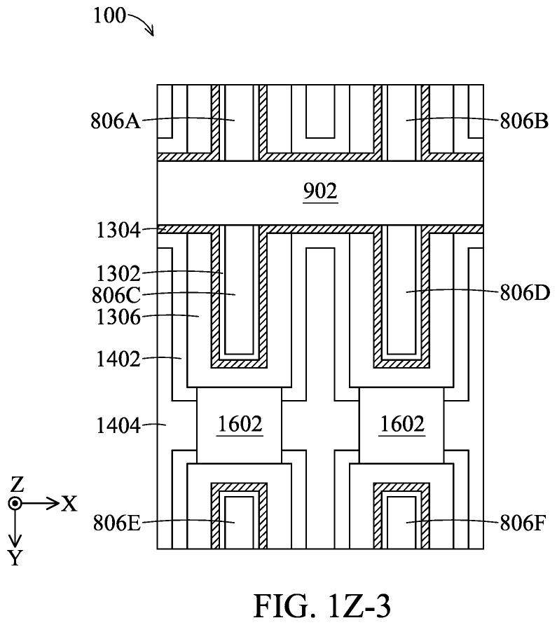

FIG. 1A is a perspective view of a portion of a workpiece 100 at a fabrication stage, in accordance with some embodiments of the present disclosure. Referring to FIG. 1A, a workpiece 100 is provided. As shown in FIG. 1A, the workpiece 100 includes a substrate 102 and a stack 104 over the substrate 102. In some embodiments, the substrate 102 contains a semiconductor material, such as bulk silicon (Si). In some other embodiments, the substrate 102 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 102 may also include an insulating layer, such as a silicon oxide layer, to have a silicon-on-insulator (SOI) structure or a germanium-on-insulator (GOI) structure. In some embodiments, the substrate 102 may include one or more well regions, such as n-type well regions doped with an n-type dopant (i.e., phosphorus (P) or arsenic (As)) or p-type well regions doped with a p-type dopant (i.e., boron (B)), for forming different types of devices. The doping the n-type wells and the p-type wells may be formed using ion implantation or thermal diffusion. In some embodiments, n-type wells have an n-type dopant concentration of about 5×10¹⁶ cm⁻³ to about 5×10¹⁹ cm⁻³, and p-type wells have a p-type dopant concentration of about 5×10¹⁶ cm⁻³ to about 5×10¹⁹ cm⁻³. Because the workpiece 100 will be fabricated into a semiconductor structure 100 upon conclusion of the fabrication processes, the workpiece 100 may be referred to as the semiconductor structure 100 as the context requires.

The stack 104 includes semiconductor layers 106A, 106B and 108 alternately stacked over the substrate 102 in the Z-direction. More specifically, the semiconductor layer 106A is formed over the substrate 102, the semiconductor layer 108 is formed over the semiconductor layer 106A, and the semiconductor layer 106B is formed over the semiconductor layer 108. In some aspects, the semiconductor layer 108 is vertically between the semiconductor layers 106A and 106B in the Z-direction.

The semiconductor layers 106A, 106B and the semiconductor layer 108 may have different semiconductor compositions. In some embodiments, semiconductor layers 106A and 106B are formed of silicon germanium (SiGe) and the semiconductor layer 108 is formed of silicon (Si). In these embodiments, the additional germanium content in the semiconductor layers 106A and 106B allow selective removal or recess of the semiconductor layers 106A and 106B without substantial damages to the semiconductor layer 108, so that the semiconductor layers 106A and 106B are also referred to as sacrificial layers. In some embodiments, the semiconductor layers 106A, 106B and the semiconductor layer 108 are epitaxially grown over (on) the substrate 102 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layer 106A, the semiconductor layer 108, and the semiconductor layer 106B are deposited alternatingly, one-after-another, to form the stack 104. It should be noted that the semiconductor layer 108 will become vertical channel layers, so that the semiconductor layer 108 may also be referred to as a channel layer.

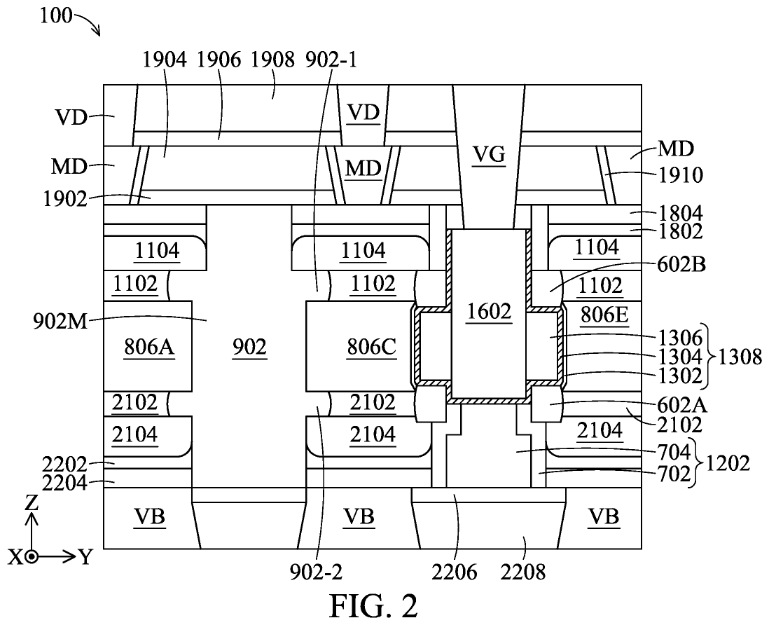

FIGS. 1B-1 to 1V-1 are top views of the portion of the workpiece 100 at various fabrication stages, in accordance with some embodiments of the present disclosure. FIGS. 1B-2 to 1V-2 are X-Z cross-sectional views of the portion of the workpiece 100 at various fabrication stages along lines A-A′ of FIGS. 1A and 1B-1 to 1V-1, in accordance with some embodiments of the present disclosure. FIGS. 1B-3 to 1V-3 are Y-Z cross-sectional views of the portion of the workpiece 100 at various fabrication stages along lines B-B′ of FIGS. 1A and 1B-1 to 1V-1, in accordance with some embodiments of the present disclosure.

Referring to FIGS. 1B-1 to 1B-3, hard mask layers 202A, 202B, 202C, and 202D (may be collectively referred to as hard mask layers 202) are formed over the stack 104 after the formation of the stack 104. Portions of the semiconductor layer 108 directly under the hard mask layers 202 may be formed as channel layers for transistors, as shown in below. It should be noted that four hard mask layers 202A, 202B, 202C, and 202D are formed over the stack 104 as shown in FIG. 1B-1, which are for illustrative purposes only and not intended to be limiting beyond what is specifically recited in the claims. The number of hard mask layers depends on the desired number of transistors. The hard mask layers 202 each may be a single layer or a multi-layer. In some embodiments, each of the hard mask layers 202 is a single layer and includes a nitride layer, such as silicon nitride. In some embodiments, each of the hard mask layers 202 is a multi-layer and includes a silicon nitride layer and a silicon oxide layer over the silicon nitride layer. In some embodiments, the hard mask layers 202 are formed by a deposition process, such as CVD, LPCVD, plasma-enhanced CVD (PECVD), a combination thereof, or the like, may also be utilized.

Referring to FIGS. 1C-1 to 1C-3, top spacers 302 are formed on sidewalls of the hard mask layers 202 and over a top surface of the stack 104 (i.e., over the semiconductor layer 106A, 108, and 106B). In some aspects, the top spacers 302 are formed on opposite sidewalls of the hard mask layers 202, as shown in FIG. 1C-2. More specifically, the top spacers 302 are formed around the hard mask layers 202, as shown in FIG. 1C-1. The top spacers 302 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), carbon doped oxide, nitrogen doped oxide, porous oxide, or combinations thereof. In some embodiments, the top spacers 302 may be formed by conformally depositing a spacer layer (containing the dielectric material) over the stack 104 and the hard mask layers 202, followed by an anisotropic etching process to remove top portions of the spacer layer from the top surfaces of the stack 104 and the hard mask layers 202. After the etching process, portions of the spacer layer on sidewall surfaces of the hard mask layers 202 substantially remain and become the top spacers 302. In some embodiments, the anisotropic etching process is a dry (e.g., plasma) etching process. Additionally or alternatively, the formation of the top spacers 302 may also involve chemical oxidation, thermal oxidation, ALD, CVD, and/or other suitable methods.

Still referring to FIGS. 1C-1 to 1C-3, the stack 104 is recessed and patterned to form trenches 402 in the stack 104 (or passing through the semiconductor layers 106B, 108, and 106A). Specifically, the trenches 402 may be formed by performing one or more etching processes to remove portions of the semiconductor layer 106B, the semiconductor layer 108, the semiconductor layer 106A, and the substrate 102 that do not vertically overlap or be covered by the hard mask layers 202 and the top spacers 302 around (or on sidewalls of) the hard mask layers 202. In some embodiments, a single etchant may be used to remove the semiconductor layer 106B, the semiconductor layer 108, the semiconductor layer 106A, and the substrate 102, whereas in other embodiments, multiple etchants may be used to perform the etching process. The semiconductor layer 108 is patterned to form channel layers vertically overlap or be covered by the hard mask layers 202 and the top spacers 302. In some embodiments, the semiconductor layer 108 is patterned to form channel layers 404A, 404B, 404C, and 404D, as shown in FIGS. 1C-1 to 1C-3. Although the channel layer 404D is not shown, it is understood that the channel layer 404D is vertically overlap or be covered by the hard mask layer 202D and the top spacer 302 around the hard mask layer 202D. The channel layers 404A, 404B, 404C, and 404D may be collectively referred to as channel layers 404. Furthermore, sidewalls of the channel layers 404 and the semiconductor layer 106A, 106B that vertically overlap or be covered by the hard mask layers 202 and the top spacers 302 are exposed in the trenches 402, as shown in FIGS. 1C-2 and 1C-3. The trenches 402 may be connected together in other region and collectively referred to as a (single) trench 402. In some embodiments, although not shown in FIGS. 1C-1 to 1C-3, top portions of the hard mask layers 202 and the top spacers 302 around the hard mask layers 202 are removed, such that heights of the hard mask layers 202 and the top spacers 302 are reduced.

Referring to FIGS. 1D-1 to 1D-3, side portions of the semiconductor layers 106A and 106B are removed via a selective etching process. Specifically, the selective etching process is performed that selectively etches the side portions of the semiconductor layers 106A and 106B below the top spacers 302 through the trenches 402, with minimal (or no) etching of the channel layers 108, so that gaps 502A are formed between the channel layers 404 and the substrate 102 and gaps 502B are formed between the top spacers 302 and the channel layers 404, as well as below the top spacers 302. The selective etching process may be a dry etching process, a wet etching process, other suitable etching process, or combinations thereof. The etching process is configured to laterally etch (e.g., along the X-direction) the semiconductor layers 106A and 106B below the top spacers 302. In some embodiments, portions of the channel layers 404 and the substrate 102 are removed during the selective etching process, so that the sidewalls of the channel layers 404 and the substrate 102 are exposed in the gaps 502A and 502B. Furthermore, portions of top surfaces of the channel layers 404 are exposed in the gaps 502B, portions of bottom surfaces of the channel layers 404 are exposed in the gaps 502A, and portions of top surfaces of the substrate 102 are exposed in the gaps 502A. As such, a thickness of the channel layers 404 directly under the top spacers 302 is less than a thickness of the channel layers 404 directly under the hard mask layers 202, as shown in FIGS. 1D-2 and 1D-3. In some aspects, sidewalls of top ends and bottom ends of the channel layers 404 are exposed in the gaps 502A and 502B. In some embodiments, the remaining semiconductor layers 106A and 106B have concave sidewalls.

Referring to FIGS. 1E-1 to 1E-3, lower inner spacers 602A are formed to fill the gaps 502A and the upper inner spacers 602B are formed to fill the gaps 502B (may be referred to as inner spacers 602A and 602B or be collectively referred to as inner spacers 602). In some embodiments, sidewalls of the inner spacers 602 are aligned to the sidewalls of the top spacers 302 and the channel layers 404, as shown in FIGS. 1E-2 and 1E-3. The lower inner spacers 602A are formed under the channel layers 404 and the upper inner spacers 602B are formed over the channel layers 404. More specifically, the lower inner spacers 602A are formed between the channel layers 404 and the substrate 102 and upper inner spacers 602B are formed between the top spacers 302 and the channel layers 404. The inner spacers 602 have convex sidewalls due to the concave sidewalls of the semiconductor layers 106A and 106B discussed above. In some embodiments, the upper inner spacers 602B are formed around the top ends of the channel layers 404 and the lower inner spacers 602A are formed around the bottom ends of the channel layers 404, as shown in FIGS. 1E-2 and 1E-3. Furthermore, a thickness of the upper inner spacers 602B in the Z-direction is greater than a thickness of the semiconductor layer 106B in the Z-direction; and a thickness of the lower inner spacers 602A in the Z-direction is greater than a thickness of the semiconductor layer 106A in the Z-direction.

In order to form the inner spacers 602, a deposition process forms a spacer layer in the trenches 402 and the gaps 502A and 502B, such as CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the trenches 402. The deposition process is configured to ensure that the spacer layer fills the gaps 502A between the channel layers 406 and the substrate 102 and the gaps 502B between the top spacers 302 and the channel layers 406. An etching process is then performed that selectively etches the spacer layer to form inner spacers 602 with minimal (to no) etching of the channel layers 404, the substrate 102, the hard mask layers 202, and the top spacers 302. The spacer layer (and thus inner spacers 602) includes a material that is different than a material of the channel layers 404 and a material of the top spacers 302 to achieve desired etching selectivity during the etching process. In some embodiments, the inner spacers 602 include a dielectric material that includes silicon, oxygen, carbon, nitrogen, other suitable material, or combinations thereof (for example, silicon oxide (SiO₂), silicon oxynitride (SiON), silicon oxycarbide (SiOC), silicon oxycarbon nitride (SiOCN)). In some embodiments, the inner spacers 602 include a low-k dielectric material, such as those described herein.

Referring to FIGS. 1F-1 to 1F-3, after the formation of the inner spacers 602, an etching process is performed to remove portions of the channel layers 406 and the substrate 102 through the trenches 402. The etching process may be an isotropic etching process, such as a wet etching process. After the etching process, the sidewalls of the channel layers 406 and the substrate 102 are not aligned with the sidewalls of the top spacers 302 and the inner spacers 602. More specifically, the sidewalls of the channel layers 406 are directly below the top spacers 302 and the upper inner spacers 602B, and the sidewalls of the substrate 102 are directly below the top spacers 302 and the inner spacers 602, as shown in FIGS. 1F-2 and 1F-3. Further, (portions of) bottom surfaces of the upper inner spacers 602B and (portions of) bottom surfaces and top surfaces of the lower inner spacers 602A are exposed in the trenches 402.

Referring to FIGS. 1G-1 to 1G-3, a liner layer 702 is conformally formed on the hard mask layer 202, the top spacers 302, the upper inner spacers 602B and the lower inner spacers 602A, the channel layers 404, and the substrate 102 in the trenches 402, and then an isolation material 704 is formed on (or inside) the liner layer 702, in some embodiments. More specifically, the liner layer 702 is conformally formed over the hard mask layer 202, the top spacers 302, and the substrate 102, and on the sidewalls of the top spacers 302, the upper inner spacers 602B, the channel layers 406, the lower inner spacers 602A, and the substrate 102. Further, the liner layer 702 is also conformally formed on the portions of the bottom surfaces of the upper inner spacers 602B and on the portions of the bottom surfaces and the top surfaces of the lower inner spacers 602A.

Next, the isolation material 704 is formed over the liner layer 702 to fill the space between the liner layer 702, such that the isolation material 704 is formed inside the liner layer 122. After the formation of the liner layer 702 and the isolation material 704, a planarization process (e.g., a chemical mechanical polishing (CMP) process) is performed until top surfaces of the hard mask layer 202 and the top spacers 302 are exposed. In some embodiments, the top portions of the hard mask layers 202 and the top spacers 302 around the hard mask layers 202 are removed, so that heights of the hard mask layers 202 and the top spacers 302 are reduced during the planarization process, as shown in FIGS. 1G-2 and 1G-3.

In some embodiments, the liner layer 702 is made of silicon nitride. The liner layer 702 is formed by a CVD, a PVD, an ALD, and/or other suitable process. In some embodiments, the isolation material 704 may be a dielectric material including silicon oxide, silicon nitride, silicon oxynitride, fluorine-doped silicate glass (FSG), a low-k dielectric, combinations thereof, and/or other suitable materials. In various embodiments, the dielectric material may be deposited by a CVD, a subatmospheric CVD (SACVD), a flowable CVD (FCVD), an ALD, spin-on coating, and/or other suitable process.

Referring to FIGS. 1H-1 to 1H-3, portions of the hard mask layers 202 (more specifically, the hard mask layers 202A and 202B), the semiconductor layer 106A, the channel layers 404 (more specifically, the channel layers 404A and 404B), the semiconductor layer 106B, the substrate 102, the liner layer 702, and the isolation material 704 are recessed or removed to form a trench 802 to cut the channel layers 404A and 404B. The trench 802 extends in the X-direction, as shown in FIG. 1H-1. In some embodiments, the trench 802 passes through the hard mask layers 202, the semiconductor layer 106A, the channel layers 404, the semiconductor layer 106B, and the liner layer 702, the isolation material 704.

The trench 802 may be formed by performing one or more etching processes to remove the portions of the hard mask layers 202, the semiconductor layer 106A, the channel layers 404, the semiconductor layer 106B, the substrate 102, the liner layer 702, and the isolation material 704. In some embodiments, a single etchant may be used to remove the hard mask layers 202, the semiconductor layer 106A, the channel layers 404, the semiconductor layer 106B, the substrate 102, the liner layer 702, and the isolation material 704, whereas in other embodiments, multiple etchants may be used to perform the etching process.

Each of the hard mask layers 202A and 202B and the channel layers 404A and 404B are cut by the trench 802 into two segments. As shown in FIGS. 1H-1 to 1H-3, the hard mask layer 202A is cut by the trench 802 into hard mask layers 804A and 804C, and the hard mask layer 202B is cut by the trench 802 into hard mask layers 804B and 804D. Furthermore, the channel layer 404A is cut by the trench 802 into channel layers 806A and 806C, and the channel layer 404B is cut by the trench 802 into channel layers 806B and 806D. Although a single trench (the trench 802) is shown in FIGS. 1H-1 and 1H-3, it is understood that more trenches are formed to cut each of the hard mask layers 202 and the channel layers 404 into two segments. Therefore, the hard mask layers 202C and 202D are cut by another trench into hard mask layers 804E and 804F, and the channel layers 404C and 404D are cut by another trench into channel layers 806E and 806F. Although the channel layers 806B and 806F are not shown, it is understood that the channel layers 806B and 806F are vertically overlap or be covered by the hard mask layers 804B and 804F, respectively. The hard mask layers 804A to 804F may be collectively referred to as hard mask layers 804. The channel layers 806A to 806F may be collectively referred to as channel layers 806. Furthermore, sidewalls of the channel layers 806A and 806C and the semiconductor layer 106A and 106B that vertically overlap or be covered by the hard mask layers 804A and 804C are exposed in the trenches 802, as shown in FIG. 1H-3. In some embodiments, the top surfaces of the substrate 102 are exposed in the trench 802.

Referring to FIGS. 1I-1 to 1I-3, a supporting structure 902 is formed in the trench 802. More specifically, a material for the supporting structure 902 is formed to fill the trench 802 and over the hard mask layers 804A to 804F, the top spacers 302, the liner layer 702, and the isolation material 704. Next, a planarization process (e.g., a CMP process) is performed on the material until top surfaces of the hard mask layers 804A to 804F, the top spacers 302, the liner layer 702, and the isolation material 704 are exposed, and the remaining material in the trench 802 becomes the supporting structure 902. The material is formed by a deposition process, such as CVD, PVD, ALD, HDPCVD, MOCVD, RPCVD, PECVD, LPCVD, ALCVD, APCVD, other suitable methods, or combinations thereof. The supporting structure is made of dielectric material, such as silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), or combinations thereof.

In some embodiments, before the formation of the supporting structure 902, side portions of the semiconductor layers 106A and 106B are removed through the trench 802. Specifically, a selective etching process is performed that selectively etches the side portions of the semiconductor layers 106A and 106B exposed in the trench 802, with minimal (or no) etching of the channel layers 806, so that gaps are formed between the channel layers 806 and the substrate 102 and between the hard mask layers 804 and the channel layers 806, as well as in the trench 802. The selective etching process is a dry etching process, a wet etching process, other suitable etching process, or combinations thereof.

Therefore, during the formation of the supporting structure 902, the material for the supporting structure 902 fills these gaps, causing the resultant supporting structure 902 to include top extending portions 902-1 and bottom extending portions 902-2, as shown in FIG. 1I-3. The top extending portions 902-1 are vertically between the hard mask layers 804 and the channel layers 806 in the Z-direction, and the bottom extending portions 902-2 are vertically between the hard mask layers 804 and the channel layers 806 and the substrate 102 in the Z-direction. In some aspects, the bottom extending portions 902-2 are under the channel layers 806 and the top extending portions 902-1 are over the channel layers 806. More specifically, portions of the channel layers 806 are vertically between the top extending portions 902-1 and the bottom extending portions 902-2, as shown in FIG. 1I-3. As such, the channel layers 806 are asymmetric about the Z-direction from the Y-Z cross-sectional view, as shown in FIG. 1I-3. Furthermore, in some embodiments, a thickness of the top extending portions 902-1 in the Z-direction is greater than the thickness of the semiconductor layer 106B in the Z-direction; and a thickness of the bottom extending portions 902-2 in the Z-direction is greater than the thickness of the semiconductor layer 106A in the Z-direction, as shown in FIG. 1I-3. In other embodiments, each of the top extending portions 902-1 and the bottom extending portions 902-2 has a convex surface (or a convex sidewall) in from the Y-Z cross-sectional view, as shown in FIG. 1I-3.

Referring to FIGS. 1J-1 to 1J-3, the hard mask layers 804 are removed by performing an etching process to form openings 1002. The etching process is a selective etching process that selectively etches the hard mask layers 804, with minimal (or no) etching of the top spacers 302, the liner layer 702, the isolation material 704, and the supporting structure 902, such that the openings 1002 are formed. The selective etching process is a dry etching process, a wet etching process, other suitable etching process, or combinations thereof. In some embodiments, top surfaces of the semiconductor layer 106B, the sidewalls of the top spacers 302, and sidewalls of the supporting structure 902 are exposed in the openings 1002, as shown in FIGS. 1J-2 and 1J-3. At this stage, a width of the openings 1002 in the X-direction and a width of topmost surfaces of the semiconductor layer 106B in the X-direction are substantially the same.

Referring to FIGS. 1K-1 to 1K-3, portions of the top spacers 302 and a top portion 902T of the supporting structure 902 exposed in the openings 1002 are laterally trimmed. In some embodiments, one or more etching processes (such as a wet etching or plasma etching) are performed to laterally etch the top spacers 302 and the supporting structure 902. Further, in some embodiments, the etching processes are configured to selectively etch the top spacers 302 and the supporting structure 902 with minimal (to no) etching of other features, such as the semiconductor layer 106B and the upper inner spacers 602B. As shown in FIG. 1K-1 to 1K-3, after the trimming of the top spacers 302 and the supporting structure 902, portions of top surfaces of the upper inner spacers 602B are exposed in the openings 1002. In some embodiments, the top extending portions 902-1 are also exposed in the openings 1002, as shown in FIG. 1J-3. At this stage, the width of the openings 1002 in the X-direction is greater than the width of the topmost surfaces of the semiconductor layer 106B in the X-direction. In some embodiments, a width of the top spacers 302 (in the X-direction shown in FIG. 1K-2 or in the Y-direction in FIG. 1K-3) is reduced. Furthermore, a width of the top portion 902T of the supporting structure 902 in the Y-direction is trimmed and reduced. As such, after the trimming of the top spacers 302 and the supporting structure 902, a width W1 of the top portion 902T of the supporting structure 902 is less than a width W2 of a middle portion 902M of the supporting structure 902 in the Y-direction, as shown in FIG. 1K-3.

Referring to FIGS. 1L-1 to 1L-3, the semiconductor layer 106B is removed by performing an etching process. The etching process is a selective etching process that selectively etches the semiconductor layer 106B, with minimal (or no) etching of the top spacers 302, the upper inner spacers 602B, the supporting structure 902, and the channel layers 806, so that top surfaces of the channel layers 406 and the (convex) sidewalls of the upper inner spacers 602B and the (convex) sidewalls of the top extending portions 902-1 of the supporting structure 902 are exposed in the openings 1002.

Referring to FIGS. 1M-1 to 1M-3, lightly doped drain (LDD) features 1102 are formed in the openings 1002, source/drain features 1104 are formed over the LDD features 1102. The LDD features 1102 have concave sidewalls due to the convex sidewalls of the upper inner spacers 602B and the top extending portions 902-1 of the supporting structure 902. In some embodiments, the LDD features 1102 are formed between and physically attached to the upper inner spacers 602B, as shown in FIG. 1M-2. In other embodiments, the LDD features 1102 are formed between and physically attached to the upper inner spacers 602B and (the top extending portions 902-1 of) the supporting structure 902, as shown in FIG. 1M-3. In some aspects, the upper inner spacers 602B and (the top extending portions 902-1 of) the supporting structure 902 are around and in contact with the LDD features 1102. In some embodiments, the LDD features 1102 are formed over and electrically connected to the channel layers 806. As shown in FIGS. 1M-2 and 1M-3, bottom surfaces of the LDD features 1102 are in contact with the top ends of the channel layers 806. Therefore, the LDD features 1102 may also be referred to as top LDD features.

As shown in FIGS. 1M-2 and 1M-3, the top surfaces of the upper inner spacers 602B and the top extending portions 902-1 of the supporting structure 902 are substantially level with top surfaces of the LDD features 1102. In some embodiments, the top extending portions 902-1 of the supporting structure 902 are in contact with the LDD features 1102 and bottom surfaces of the top extending portions 902-1 are lower than the bottom surfaces of the LDD features 1102, as shown in FIG. 1M-3. Therefore, in some embodiments, a thickness of the top extending portions 902-1 is greater than a thickness of the LDD features 1102, as shown in FIG. 1M-3.

The source/drain features 1104 have convex top surfaces, as shown in FIGS. 1M-2 and 1M-3. In some embodiments, the source/drain features 1104 are formed between and in contact with the top spacers 302 and the supporting structure 902. In some aspects, the top spacers 302 and the supporting structure 902 are around and in contact with the source/drain features 1104. As shown in FIGS. 1M-2 and 1M-3, bottom surfaces of the source/drain features 1104 are substantially level with the top surfaces of the upper inner spacers 602B and the top extending portions 902-1 of the supporting structure 902. In some embodiments, the source/drain features 1104 are formed over and electrically connected to the channel layers 806 and the LDD features 1102. As shown in FIGS. 1M-2 and 1M-3, the bottom surfaces of the source/drain features 1104 are in contact with the LDD features 1102, the upper inner spacers 602B, and (the top extending portions 902-1 of) the supporting structure 902. Therefore, the source/drain features 1104 may also be referred to as top source/drain features.

One or more epitaxy processes may be employed to grow the LDD features 1102 and the source/drain features 1104. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The LDD features 1102 and the source/drain features 1104 may include any suitable semiconductor materials.

For example, the LDD features 1102 and the source/drain features 1104 for n-type VGAA transistors may include epitaxially-grown material selected from a group consisting of SiP, SiC, SiPC, SiAs, Si, or a combination thereof. In some embodiments, the epitaxially-grown material of the LDD features 1102 and the source/drain features 1104 may be doped with n-type dopants (such as phosphorus, arsenic, other n-type dopant, or combinations thereof). The n-type dopant concentration of the LDD features 1102 is less than the n-type dopant concentration of the source/drain features 1104. In some embodiments, the LDD features 1102 and the source/drain features 1104 for n-type VGAA transistors may be respectively referred to as n-type LDD features and n-type source/drain features.

In another example, the LDD features 1102 and the source/drain features 1104 for p-type VGAA transistors may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the LDD features 1102 and the source/drain features 1104 may be doped with p-type dopants (such as boron, indium, other p-type dopant, or combinations thereof). The p-type dopant concentration of the LDD features 1102 is less than the p-type dopant concentration of the source/drain features 1104. In some embodiments, the LDD features 1102 and the source/drain features 1104 for p-type VGAA transistors may be respectively referred to as p-type LDD features and p-type source/drain features.

The source/drain features 1104 may also be referred to as source/drain, or source/drain regions. In some embodiments, the source/drain features 1104 may refer to a source or a drain, individually or collectively dependent upon the context. The LDD features 1102 and the source/drain features 1104 may be doped in-situ or ex-situ. One or more annealing processes may be performed to activate the dopants in the LDD features 1102 and the source/drain features 1104. The annealing processes may include rapid thermal annealing (RTA) and/or laser annealing processes.

Still Referring to FIGS. 1M-1 to 1M-3, hard mask layers 1106 are formed over the source/drain features 1104. In order to form the hard mask layers 1106, a deposition process forms a dielectric material into the openings 1002 and over the top spacers 302, the liner layer 702, the isolation material 704, and the source/drain features 1104. A planarization process (e.g., a chemical mechanical polishing (CMP) process) is then performed on the dielectric material until the top surfaces of the top spacers 302, the supporting structure 902, the liner layer 702, and the isolation material 704 are exposed, and thereby the remaining dielectric materials in the openings 1002 become the hard mask layers 1106.

The hard mask layers 1106 have concave bottom surfaces due to the convex top surfaces of the source/drain features 1104. In some embodiments, the hard mask layers 1106 are formed between and in contact with the top spacers 302 and the supporting structure 902. In some aspects, the top spacers 302 and the supporting structure 902 are around and in contact with the hard mask layers 1106. The hard mask layers 1106 each may be a single layer or a multi-layer. In some embodiments, each of the hard mask layers 1106 is a single layer and includes a nitride layer, such as silicon nitride. In some embodiments, each of the hard mask layers 1106 is a multi-layer and includes a silicon nitride layer and a silicon oxide layer over the silicon nitride layer. In some embodiments, the deposition process for forming the dielectric material of the hard mask layers 1106 includes CVD, LPCVD, plasma-enhanced CVD (PECVD), a combination thereof, or the like, may also be utilized.

Referring to FIGS. 1N-1 to 1N-3, the liner layer 702 and the isolation material 704 are recessed to form isolation structure 1202. More specifically, an etching process is performed to remove portions of the liner layer 702 and the isolation material 704 to form trenches 1204, and remaining portions of the liner layer 702 and the isolation material 704 are formed into isolation structure 1202. The etching process may be an isotropic etching process, such as a wet etching process. In some embodiments, the etching process is a selective etching process that selectively etches the liner layer 702 and the isolation material 704, with minimal (or no) etching of the hard mask layers 1106, the top spacers 302, the supporting structure 902, the upper inner spacers 602B, the channel layers 806, and the lower inner spacers 602A. The trenches 1204 may be connected together in other region and collectively referred to as a single trench.

After the recessing of the liner layer 702 and the isolation material 704, the sidewalls of the top spacers 302, the upper inner spacers 602B, the channel layers 806, and the lower inner spacers 602A are exposed in the trenches 1204, as shown in FIGS. 1N-2 and 1N-3. It is noted that top portions of the sidewalls of the lower inner spacers 602A are exposed. The bottom portions of the sidewalls of the lower inner spacers 602A are covered by the isolation structure 1202 (more specifically, the liner layer 702). As shown in FIGS. 1N-2 and 1N-3, the isolation structure 1202 is between the lower inner spacers 602A. Further, top surfaces of the isolation structure 1202 are lower than the top surfaces of the lower inner spacers 602A and the bottom surfaces of the channel layers 806. In some embodiments, the top surfaces of the isolation structure 1202 are higher than the top surfaces of the substrate 102.

Referring to FIGS. 1O-1 to 1O-3, portions of the channel layers 806 exposed in the trenches 1204 are trimmed. More specifically, the channel layers 806 are trimmed to remove the portions of the channel layers 806 vertically between the upper inner spacers 602B and the lower inner spacers 602A and exposed in the trenches 1204, as shown in FIGS. 1O-2 and 1O-3. In some embodiments, one or more etching processes (such as a wet etching or plasma etching) are performed to laterally etch the channel layers 806 along the X-direction and the Y-direction. The etching processes may also reduce a width (in the X-direction) of the channel layers 806. Further, in some embodiments, the etching processes are configured to selectively etch the channel layers 806 with minimal (to no) etching of other features, such as top spacers 302, the upper inner spacers 602B, the lower inner spacers 602A, and the isolation structure 1202 (the liner layer 702 and the isolation material 704).

As shown in FIG. 10-2, after the trimming of the channel layers 806, each of the channel layers 806 have an I-shaped structure in the X-Z cross-sectional view. More specifically, widths of the top ends and the bottom ends of the channel layers 806 in the X-direction are greater than a width of middle portions of the channel layers 806 in the X-direction. In some aspects, the channel layers 806 have concave sidewalls, as shown in FIGS. 1O-2 and 1O-3. In other embodiments, the channel layers 806 have a pillar structure with vertical sidewalls. As shown in FIG. 10-2, the channel layers 806 are perpendicular to the isolation structure 1202 and the substrate 102. Further, the channel layers 806 extend in the Z-direction perpendicular to the X-direction and the Y-direction (or in a normal line of an X-Y plane). As such, the resultant transistors with the channel layers 806 are formed into VGAA transistors.

As discussed above, the upper inner spacers 602B are formed in contact with and around the top ends of the channel layers 806, and the lower inner spacers 602A are formed in contact with and around the bottom ends of the channel layers 806. In some embodiments, the top surfaces of the channel layers 806 are higher than bottom surfaces of the upper inner spacers 602B. The bottom surfaces of the channel layers 806 are lower than the top surfaces of the lower inner spacers 602A.

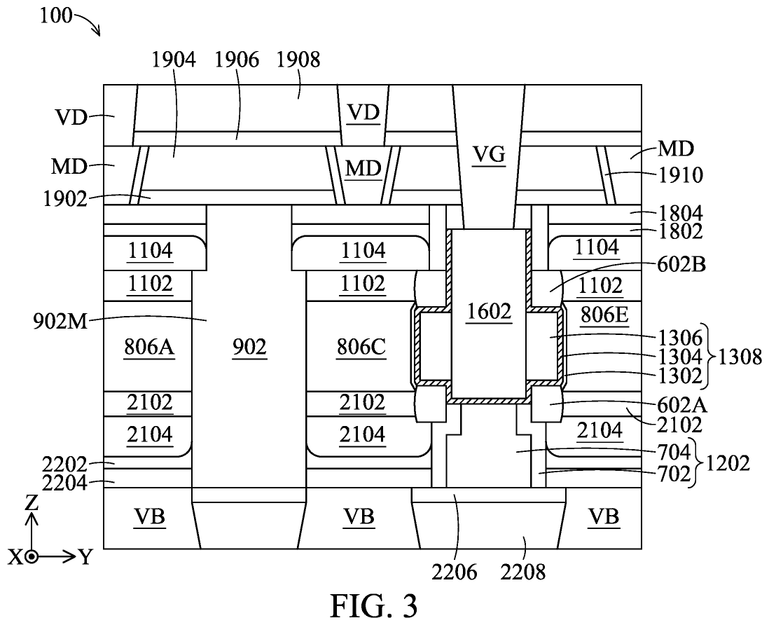

As shown in FIG. 10-2, in the X-Z cross-sectional view, the channel layers 806, the upper inner spacers 602B, the LDD features 1102, the source/drain features 1104, the hard mask layers 1106, and the top spacers 302 are constructed to form hammer-like structures after the trimming of the channel layers 806. Compared to the trimmed and thinned channel layers 806, the features (the upper inner spacers 602B, the LDD features 1102, the source/drain features 1104, the hard mask layers 1106, and the top spacers 302) over the channel layers 806 are large and heavy. Such structures may cause collapses, thereby breaking the resultant VGAA transistors. However, in the present embodiments, the supporting structure 902 is formed to support the features (the channel layers 806, the upper inner spacers 602B, the LDD features 1102, the source/drain features 1104, the hard mask layers 1106, and the top spacers 302). More specifically, the supporting structure 902 supports and is in contact with the channel layers 806, the LDD features 1102, the source/drain features 1104, and the hard mask layers 1106 in the Y-direction, as shown in FIG. 10-3. Although not shown in FIG. 10-3, it should be noted and understood that the supporting structure 902 also supports and is in contact with the upper inner spacers 602B and the top spacers 302 in other cross-sectional views. Therefore, the collapses caused by the hammer-like structures discussed above are prevented.

Referring to FIGS. 1P-1 to 1P-3, gate structures 1308 are formed in the trenches 1204 to laterally wrap around the channel layers 806. In some embodiments, each of the gate structures 1308 includes an interfacial layer 1302, a gate dielectric layer 1304, and a gate electrode layer 1306. The interfacial layers 1302 are formed to laterally wrap around the channel layers 806. More specifically, the interfacial layers 1302 are formed on the sidewalls of the channel layers 806 exposed in the trenches 1204. In some embodiments, the interfacial layers 1404 may include a dielectric material such as silicon oxide (SiO₂), HfSiO, or silicon oxynitride (SiON). The interfacial layers 1404 may be formed by chemical oxidation, thermal oxidation, ALD, CVD, and/or other suitable method.

The gate dielectric layer 1304 is formed to laterally wrap around the channel layers 806 and the interfacial layers 1302, as shown in FIGS. 1P-2 and 1P-3. More specifically, the gate dielectric layer 1304 is conformally formed over the hard mask layers 1106, the top spacers 302, the supporting structure 902, and the isolation structure 1202, on the sidewalls of the top spacers 302, the upper inner spacers 602B, the lower inner spacers 602A, and the interfacial layers 1302. Further, the gate dielectric layer 1304 is also formed on the bottom surfaces of the upper inner spacers 602B and the top surfaces of the lower inner spacers 602A. The interfacial layers 1302 are between the gate dielectric layer 1304 and the channel layers 806. In other words, the gate dielectric layer 1304 is separated from the channel layers 806 by the interfacial layers 1302.

The gate dielectric layer 1304 may include a dielectric material having a dielectric constant greater than a dielectric constant of SiO₂, which is approximately 3.9. For example, the gate dielectric layer 1304 may include hafnium oxide (HfO₂), which has a dielectric constant in a range from about 18 to about 40. Alternatively, the gate dielectric layer 1304 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba, Sr) TiO₃ (BST), Al₂O₃, Si₃N₄, oxynitrides (SiON), combinations thereof, or other suitable material. The gate dielectric layer 1304 may be formed by ALD, PVD, CVD, oxidation, and/or other suitable methods.

The gate electrode layers 1306 are formed to laterally wrap around the channel layers 806, the interfacial layers 1302, and the gate dielectric layer 1304, as shown in FIGS. 1P-2 and 1P-3. More specifically, one or more material for the gate electrode layers 1306 are formed on the gate dielectric layer 1304 to fill the trenches 1204. Next, an etching process may be performed to remove portions of the material directly over the isolation structure 1202 and in the trenches 1204. In some embodiments, the etching process is a selective etching process that selectively etches the material for the gate electrode layers 1306, with minimal (or no) etching of the gate dielectric layer 1304. The etching process is also an anisotropic etching process, so that (other portions of) the material for the gate electrode layers 1306 directly below the top spacers 302, the upper inner spacers 602B, and the gate dielectric layer 1304 remain to form the gate electrode layers 1306. In some embodiments, the gate electrode layers 1306 are vertically between the upper inner spacers 602B and the lower inner spacers 602A in the Z-direction. As shown in FIGS. 1P-2 and 1P-3, sidewalls of the gate electrode layers 1306 are aligned with sidewalls of the gate dielectric layer 1304.

In some embodiments, the one or more material for the gate electrode layers 1306 are conductive materials, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layers 1306 are formed using CVD, PVD, ALD, electroplating, another applicable method, or a combination thereof.

In some embodiments, the gate electrode layers 1306 include n-type work function metal layer. In an embodiment, the n-type work function metal layer is a material such as Ti, Al, Ag, Mn, Zr, TiAl, TiAlC, TaC, TaCN, TaSiN, TaAl, TaAlC, TiAlN, other suitable n-type work function materials, or combinations thereof. For example, the n-type work function metal layer may be deposited utilizing ALD, CVD, or the like. However, any suitable materials and processes may be utilized to form the n-type work function metal layer.

In some embodiments, the gate electrode layers 1306 include p-type work function metal layer. In an embodiment, the p-type work function metal layer may be a material such as TIN, TaN, Ru, Mo, Al, WN, ZrSi2, MoSi2, TaSi2, NiSi2, WN, other metal oxides, metal nitrides, metal silicates, transition metal-oxides, transition metal-nitrides, transition metal-silicates, oxynitrides of metals, metal aluminates, zirconium silicate, zirconium aluminate, other suitable p-type work function materials, combinations of these, or the like. Additionally, the p-type work function metal layer may be deposited using a deposition process such as ALD, CVD, or the like, although any suitable deposition process may be used.

Referring to FIGS. 1Q-1 to 1Q-3, a contact etch stop layer (CESL) 1402 over the isolation structure 1202 in the trenches 1204 and an interlayer dielectric (ILD) layer 1404 over the CESL 1402 are formed to fill the space in the trenches 1204. Specifically, the CESL 1402 is conformally formed on the sidewalls of the gate dielectric layer 1304 and the gate electrode layers 1306, over top surfaces of the gate dielectric layer 1304, as shown in FIGS. 1Q-2 and 1Q-3

The ILD layer 1404 is formed over and between the CESL 1002 to fill a remaining space between (or inside) the CESL 1402. The CESL 1402 includes a material that is different than ILD layer 1404. The CESL 1402 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The ILD layer 1404 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD 1404 may be formed by PECVD (plasma enhanced CVD), FCVD (flowable CVD), or other suitable methods.

Referring to FIGS. 1R-1 to 1R-3, portions of the CESL 1402 and the ILD layer 1404 are removed and recessed by performing one or more lithography and etching processes to form openings 1502. The etching process may be an anisotropic etching process, such as a dry etching process. In some embodiments, the etching process is a selective etching process that selectively etches the CESL 1402 and the ILD layer 1404, with minimal (or no) etching of the gate dielectric layer 1304 and the gate electrode layers 1306. After the removal of the portions of the CESL 1402 and the ILD layer 1404, the sidewalls of the gate electrode layers 1306 are exposed in the openings 1502. For example, the sidewalls of the gate electrode layers 1306 wrapping around the channel layers 806C and 806E are exposed in the openings 1502, as shown in FIG. 1R-3. It should be noted that more openings are formed to expose the sidewalls of the gate electrode layers 1306 for sequent process for metal conductors in below. In some embodiments, as shown in FIGS. 1R-2 and 1R-3, a top portion of the ILD layer 1404 is removed, so that a height of the ILD layer 1404 is reduced.

Referring to FIGS. 1S-1 to 1S-3, metal conductors 1602 are formed in the openings 1502. More specifically, a conductive material is formed in the openings 1502 and over the ILD layer 1404, and a planarization process (e.g., a chemical mechanical polishing (CMP) process) is then performed on the conductive material until a top surface of ILD layer 1404 is exposed, thereby the remaining conductive materials in the openings 1502 become the metal conductors 1602. The metal conductors 1602 are in contact with and electrically connected to (the sidewalls of) the gate electrode layers 1306. The materials of metal conductors 1602 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof. In some embodiments, as shown in FIGS. 1S-2 and 1S-3, the top portion of the ILD layer 1404 is removed, so that the height of the ILD layer 1404 is reduced.

Referring to FIGS. 1T-1 to 1T-3, top portions of the metal conductors 1602 are replaced with hard mask layers 1702. More specifically, the top portions of the metal conductors 1602 in the openings 1502 are removed and a material for the hard mask layers 1702 is then formed over the metal conductors 1602 in the openings 1502 and the ILD layer 1404. Next, a planarization process (e.g., a chemical mechanical polishing (CMP) process) is performed on the material for the hard mask layers 1702 until the top surface of ILD layer 1404 is exposed, thereby the remaining materials for the hard mask layers 1702 in the openings 1502 become the hard mask layers 1702. The hard mask layers 1702 each may be a single layer or a multi-layer. In some embodiments, each of the hard mask layers 1702 is a single layer and includes a nitride layer, such as silicon nitride. In some embodiments, each of the hard mask layers 1106 is a multi-layer and includes a silicon nitride layer and a silicon oxide layer over the silicon nitride layer. In some embodiments, the hard mask layers 1702 may include a dielectric material, such as SiO₂, SiOC, SiON, SiOCN, nitride-based dielectric, metal oxide dielectric, HfO₂, Ta₂O₅, TiO₂, ZrO₂, Al₂O₃, Y₂O₃, or combinations thereof. In some embodiments, the deposition process for forming the dielectric material of the hard mask layers 1106 includes CVD, LPCVD, plasma-enhanced CVD (PECVD), a combination thereof, or the like, may also be utilized.

Referring to FIGS. 1U-1 to 1U-3, a planarization process (e.g., a chemical mechanical polishing (CMP) process) is performed on the workpiece 100 to remove portions of the CESL 1402, the ILD layer 1404, the hard mask layers 1702, the hard mask layers 1106, the supporting structure 902, and the top spacers 302, thereby exposing top surfaces of the hard mask layers 1106.

Referring to FIGS. 1V-1 to 1V-3, the hard mask layers 1106 are replaced with silicide layers 1802 over the source/drain features 1104 and source/drain pads 1804 over the silicide layers 1802. More specifically, the hard mask layers 1106 are removed to expose the source/drain features 1104; and the silicide layers 1802 and the source/drain pads 1804 are formed over the exposed source/drain features 1104. The silicide layers 1802 are over and electrically connected to the source/drain features 1104. In some embodiments, the silicide layers 1802 are formed between and in contact with the top spacers 302 and the supporting structure 902. In some aspects, the top spacers 302 and the supporting structure 902 are around and in contact with the silicide layers 1802.

The silicide layers 1802 may include titanium, nickel, cobalt, or erbium in order to reduce the Schottky barrier height of the source/drain contact features 1104. However, other metals, such as platinum, palladium, and the like, may also be used. The silicidation may be performed by blanket deposition of an appropriate metal layer, followed by an annealing step which causes the metal to react with the underlying exposed silicon. Un-reacted metal is then removed, such as with a selective etch process. In some embodiments, the silicide layers 1802 have concave bottom surfaces due to the convex top surfaces of the source/drain features 1104.

The source/drain pads 1804 are over and electrically connected to the silicide layers 1802 and the source/drain features 1104. In some embodiments, the source/drain pads 1804 are formed between and in contact with the top spacers 302 and the supporting structure 902. In some aspects, the top spacers 302 and the supporting structure 902 are around and in contact with the source/drain pads 1804.

The source/drain pads 1804 may include conductive material, such as Al, Cu, W, Co, Ti, Ta, Ru, Rh, Ir, Pt, TIN, TiAl, TiAlN, TaN, TaC, combinations of these, or the like, although any suitable material may be deposited using a deposition process such as sputtering, CVD, electroplating, electroless plating, or the like. In some embodiments, the source/drain pads 1804 may include single conductive material layer or multiple conductive layers. The source/drain pads 1804 may be referred to as source/drain contacts.

FIGS. 1W-1 to 1Z-1 are X-Z cross-sectional views of the portion of the workpiece 100 at various fabrication stages along lines A-A′ of FIGS. 1A and 1B-1 to 1V-1, in accordance with some embodiments of the present disclosure. FIGS. 1W-2 to 1Z-2 are Y-Z cross-sectional views of the portion of the workpiece 100 at various fabrication stages along lines B-B′ of FIGS. 1A and 1B-1 to 1V-1, in accordance with some embodiments of the present disclosure.

Referring to FIGS. 1W-1 and 1W-2, a front-side interconnection structure is formed over the workpiece 100. The front-side interconnection structure includes, a CESL 1902, an ILD layer 1904, a CESL 1906, an ILD layer 1908, metal conductors MD (including metal conductors MD1, MD2, and MD3), and vias VD and VG. The CESL 1902 is formed over the source/drain pads 1804, the supporting structure 902, the hard mask layers 1702, the top spacers 302, the CESL 1402, and the ILD layer 1404; the ILD layer 1904 is formed over the CESL 1902; the CESL 1906 is formed over the ILD layer 1904; and the ILD layer 1908 is formed over the CESL 1906. The CESLs 1902 and 1906 include a material similar to the material of the CESL 1402 discussed above. The ILD layers 1904 and 1908 include a material similar to the material of the ILD layer 1404 discussed above.

The metal conductors MD are formed passing through the CESL 1902 and the ILD layer 1904. Each of the metal conductors MD is surrounded by a barrier layer 1910. Furthermore, each of the metal conductors MD is in direct contact with two adjacent source/drain pads 1804, so that each of the metal conductors MD is electrically connected to two adjacent source/drain pads 1804, two adjacent silicide layers 1802, and two adjacent source/drain features 1104, as shown in FIG. 1W-1. In some embodiments, portions of the top spacers 302 are removed during the formation of the metal conductors MD. As such, the metal conductors MD are in contact sidewalls of the source/drain pads 1804, as shown in FIG. 1W-1.

The vias VD are formed passing through the CESL 1906 and the ILD layer 1908. The vias VD are also formed over and in contact with the metal conductors MD, so that the vias VD are electrically connected to the metal conductors MD, as shown in FIGS. 1W-1 and 1W-2. The via VG are formed passing through the CESL 1902, the ILD layer 1904, the CESL 1906, the ILD layer 1908, and the hard mask layer 1702. The via VG is also formed over and in contact with the metal conductor 1602, so that the via VG is electrically connected to the metal conductor 1602 and the gate electrode layers 1306, as shown in FIG. 1W-2. Although one via VG is shown in FIG. 1W-3, it is understood that more vias VG are formed over and in contact with the metal conductors 1602.

The materials of the vias VD and VG, and the metal conductors MD are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

After the formation of the front-side interconnection structure, the workpiece 100 may be flipped to form subsequent features. For the purpose of simplicity, the sequent figures are shown without being flipped. Referring to FIGS. 1X-1 and 1X-2, the substrate 102 is removed by performing one or more etching processes on a bottom surface of the substrate 102 (or on a back-side of the substrate 102) to form openings 2002. The etching process is a selective etching process that selectively etches the substrate 102, with minimal (or no) etching of the isolation structure 1202 (more specifically, the liner layer 702), the lower inner spacers 602A, and the semiconductor layer 106A, so that the openings 2002 are formed. The selective etching process is a dry etching process, a wet etching process, other suitable etching process, or combinations thereof. As such, bottom surfaces of the isolation structure 1202 (more specifically, the liner layer 702), the lower inner spacers 602A, and the semiconductor layer 106A are exposed. In some aspects, bottom surfaces of the semiconductor layer 106A, (portions of) the bottom surfaces of the lower inner spacers 602A, and sidewalls of the isolation structure 1202 (more specifically, the liner layer 702) are exposed in the openings 2002, as shown in FIGS. 1X-1 and 1X-2.

Referring to FIGS. 1Y-1 and 1Y-2, the semiconductor layer 106A is removed, and lightly doped drain (LDD) features 2102 are formed in the openings 2002, and source/drain features 2104 are formed under the LDD features 2102. The LDD features 2102 have concave sidewalls due to the convex sidewalls of the lower inner spacers 602A and the bottom extending portions 902-2 of the supporting structure 902. In some embodiments, the LDD features 2102 are formed between and physically attached to the lower inner spacers 602A, as shown in FIG. 1Y-1. In other embodiments, the LDD features 2102 are formed between and physically attached to the lower inner spacers 602A and (the bottom extending portions 902-2 of) the supporting structure 902, as shown in FIG. 1Y-2. In some aspects, the lower inner spacers 602B and (the bottom extending portions 902-2 of) the supporting structure 902 are around and in contact with the LDD features 2102. In some embodiments, the LDD features 2102 are formed under and electrically connected to the channel layers 806. As shown in FIGS. 1Y-1 and 1Y-2, top surfaces of the LDD features 2102 are in contact with the bottom ends of the channel layers 806. Therefore, the LDD features 2102 may also be referred to as bottom LDD features.

As shown in FIGS. 1Y-1 and 1Y-2, the top surfaces of the bottom inner spacers 602A and the bottom extending portions 902-2 of the supporting structure 902 are higher than the top surfaces of the LDD features 2102. In some embodiments, the bottom extending portions 902-2 of the supporting structure 902 are in contact with the LDD features 2102 and bottom surfaces of the bottom extending portions 902-2 are lower than the bottom surfaces of the LDD features 2102, as shown in FIG. 1Y-2. Therefore, in some embodiments, a thickness of the bottom extending portions 902-2 is greater than a thickness of the LDD features 2102, as shown in FIG. 1Y-2.

The source/drain features 2104 have convex bottom surfaces, as shown in FIGS. 1Y-1 and 1Y-2. In some embodiments, the source/drain features 2104 are formed between and in contact with the liner layer 702 and the supporting structure 902. In some aspects, the liner layer 702 and the supporting structure 902 are around and in contact with the source/drain features 2104. As shown in FIGS. 1Y-1 and 1Y-2, top surfaces of the source/drain features 2104 are higher than the bottom surfaces of the lower inner spacers 602A and the bottom extending portions 902-2 of the supporting structure 902. In some embodiments, the source/drain features 2104 are formed under and electrically connected to the channel layers 806 and the LDD features 2102. As shown in FIGS. 1Y-1 and 1Y-2, the top surfaces of the source/drain features 2104 are in contact with the LDD features 2102, the lower inner spacers 602A, and (the bottom extending portions 902-2 of) the supporting structure 902 . . . . Therefore, the source/drain features 2104 may also be referred to as bottom source/drain features.

One or more epitaxy processes may be employed to grow the LDD features 2102 and the source/drain features 2104. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The LDD features LDD features 2102 and the source/drain features 2104 may include any suitable semiconductor materials.

For example, the LDD features 2102 and the source/drain features 2104 for n-type VGAA transistors may include epitaxially-grown material selected from a group consisting of SiP, SiC, SiPC, SiAs, Si, or a combination thereof. In some embodiments, the epitaxially-grown material of the LDD features 2102 and the source/drain features 2104 may be doped with n-type dopants (such as phosphorus, arsenic, other n-type dopant, or combinations thereof). The n-type dopant concentration of the LDD features 2102 is less than the n-type dopant concentration of the source/drain features 2104. In some embodiments, the LDD features 2102 and the source/drain features 2104 for n-type VGAA transistors may be respectively referred to as n-type LDD features and n-type source/drain features.

In another example, the LDD features 2102 and the source/drain features 2104 for p-type VGAA transistors may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the LDD features 2102 and the source/drain features 2104 may be doped with p-type dopants (such as boron, indium, other p-type dopant, or combinations thereof). The p-type dopant concentration of the LDD features 2102 is less than the p-type dopant concentration of the source/drain features 2104. In some embodiments, the LDD features 2102 and the source/drain features 2104 for p-type VGAA transistors may be respectively referred to as p-type LDD features and p-type source/drain features.

The source/drain features 2104 may also be referred to as source/drain, or source/drain regions. In some embodiments, the source/drain features 2104 may refer to a source or a drain, individually or collectively dependent upon the context. The LDD features 2102 and the source/drain features 2104 may be doped in-situ or ex-situ. One or more annealing processes may be performed to activate the dopants in the LDD features 2102 and the source/drain features 2104. The annealing processes may include rapid thermal annealing (RTA) and/or laser annealing processes.

Referring to FIGS. 1Z-1 and 1Z-2, the silicide layers 2202 and the source/drain pads 2104 are formed under the source/drain features 2104. The silicide layers 2202 are under and electrically connected to the source/drain features 2104. In some embodiments, the silicide layers 2202 are formed between and in contact with the liner layer 702 and the supporting structure 902. In some aspects, the liner layer 702 and the supporting structure 902 are around and in contact with the silicide layers 2202.

The silicide layers 2202 may include titanium, nickel, cobalt, or erbium in order to reduce the Schottky barrier height of the source/drain contact features 2104. However, other metals, such as platinum, palladium, and the like, may also be used. The silicidation may be performed by blanket deposition of an appropriate metal layer, followed by an annealing step which causes the metal to react with the underlying exposed silicon. Un-reacted metal is then removed, such as with a selective etch process. In some embodiments, the silicide layers 2202 have concave top surfaces due to the convex bottom surfaces of the source/drain features 2104.

The source/drain pads 2204 are under and electrically connected to the silicide layers 2202 and the source/drain features 2104. In some embodiments, the source/drain pads 2204 are formed between and in contact with the liner layer 702 and the supporting structure 902. In some aspects, the liner layer 702 and the supporting structure 902 are around and in contact with the source/drain pads 2204.

The source/drain pads 2204 may include conductive material, such as Al, Cu, W, Co, Ti, Ta, Ru, Rh, Ir, Pt, TiN, TiAl, TiAlN, TaN, TaC, combinations of these, or the like, although any suitable material may be deposited using a deposition process such as sputtering, CVD, electroplating, electroless plating, or the like. In some embodiments, the source/drain pads 2204 may include single conductive material layer or multiple conductive layers. The source/drain pads 2204 may be referred to as source/drain contacts.

Still referring to FIGS. 1Z-1 and 1Z-2, after the formation of the silicide layers 2202 and the source/drain pads 2204, a back-side interconnection structure is formed under the workpiece 100 to complete the formation of the VGAA transistors. The back-side interconnection structure includes, a CESL 2206, an ILD layer 2208, and vias VB. It is noted that bottom portions of the supporting structure 902 and the isolation structure 1202 are removed by a planarization process (e.g., a CMP process) during the formation of the source/drain pads 2204, so that bottom surface of the supporting structure 902 and the isolation structure 1202 are planar and level with bottom surfaces of the source/drain pads 2204. The CESL 2206 is formed under the source/drain pads 2204, the supporting structure 902, and the isolation structure 1202; and the ILD layer 2208 is formed under the CESL 1902. The CESL 2206 includes a material similar to the material of the CESLs 1402, 1902, and 1906 discussed above. The ILD layer 2208 includes a material similar to the material of the ILD layers 1404, 1904, and 1908 discussed above.

The vias VB are formed passing through the CESL 2206 and the ILD layer 2208. The vias VB are also formed under and in contact with the source/drain pads 2204, so that the vias VB are electrically connected to the source/drain pads 2204, the silicide layers 2202, and the source/drain features 2104, as shown in FIGS. 1Z-1 and 1Z-2. The materials of the vias VB are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

FIG. 1Z-3 is an X-Y cross-sectional view of the portion of the workpiece 100 at a fabrication stage along a line C-C′ of FIG. 1Z-2, in accordance with some embodiments of the present disclosure. Referring to FIG. 1Z-3, the interfacial layers 1302 and the gate dielectric layer 1304 further extend onto opposite sidewalls of the channel layers 806 and are in contact with the supporting structure 902. Furthermore, the gate dielectric layer 1304 further extends onto the sidewalls of the supporting structure 902 to separate the supporting structure 902 from the CESL 1402. In some embodiments, each of the gate electrode layers 1306 has a U-shape in the X-Y cross-sectional view of FIG. 1Z-3. The supporting structure 902 is also separated from the gate electrode layers 1306 by the gate dielectric layer 1304.

As the resultant structure shown in FIG. 1Z-1 to 1Z-3, the supporting structure 902 is in contact with the source/drain pads 1804, the silicide layers 1802, the source/drain features 1104, the LDD features 1102, the channel layers 806, the LDD features 2102, the source/drain features 2104, the silicide layers 2202, and the source/drain pads 2204 in the Y-direction. The top extending portions 902-1 of the supporting structure 902 are vertically between the source/drain features 1104 and the channel layers 806; and the bottom extending portions 902-2 of the supporting structure 902 are vertically between the source/drain features 2104 and the channel layers 806.

As discussed, the width of the top portion 902T of the supporting structure 902 in the Y-direction is trimmed and reduced. In some embodiments, the width W1 of the top portion 902T of the supporting structure 902 in contact with the source/drain features 1104, the silicide layers 1802, and the source/drain pads 1804 in the Y-direction is in a range from about 10 nm to about 100 nm. In some embodiments, the width W2 of the middle portion 902M of the supporting structure 902 in contact with the channel layers 806 in the Y-direction is in a range from about 20 nm to about 100 nm. In some embodiments, the supporting structure 902 has a height H in a range from about 30 nm to about 150 nm in the Z-direction, as shown in FIG. 1Z-2.

As discussed above, the portions of the channel layers 806 are vertically between the top extending portions 902-1 and the bottom extending portions 902-2. As shown in FIG. 1Z-2, a thickness of the portions of the channel layers 806 are less than a thickness of the portions of the channel layers 806 vertically between the LDD features 1102 and the LDD features 2102. Therefore, the channel layers 806 are asymmetric about the Z-direction from the Y-Z cross-sectional view, as discussed above. Furthermore, the LDD features 1102 and 2102 cover the sidewalls of the supporting structure 902. More specifically, the LDD features 1102 cover the sidewalls of top extending portions 902-1 of the supporting structure 902; and the LDD features 2102 cover the sidewalls of bottom extending portions 902-2 of the supporting structure 902.

FIG. 2 is a Y-Z cross-sectional view of the portion of the workpiece 100 at a fabrication stage corresponding to FIG. 1Z-2 and along lines B-B′ of FIGS. 1A and 1B-1 to 1V-1, in accordance with some embodiments of the present disclosure. As shown in FIG. 2, the thickness of the top extending portions 902-1 of the supporting structure 902 and the thickness of the LDD features 1102 are the same; and the thickness of the bottom extending portions 902-2 of the supporting structure 902 and the thickness of the LDD features 2102 are the same. In other words, the top surfaces and the bottom surfaces of the top extending portions 902-1 of the supporting structure 902 are respectively substantially level with the top surfaces and the bottom surfaces of the LDD features 1102; and the top surfaces and the bottom surfaces of the bottom extending portions 902-2 of the supporting structure 902 are respectively substantially level with the top surfaces and the bottom surfaces of the LDD features 2102. In some embodiments, the thickness of the portions of the channel layers 806 and the thickness of the portions of the channel layers 806 vertically between the LDD features 1102 and the LDD features 2102 are the same. As such, the channel layers 806 are symmetric about the Z-direction from the Y-Z cross-sectional view, as shown in FIG. 2.

FIG. 3 is a Y-Z cross-sectional view of the portion of the workpiece 100 at a fabrication stage corresponding to FIG. 1Z-2 and along lines B-B′ of FIGS. 1A and 1B-1 to 1V-1, in accordance with some embodiments of the present disclosure. The supporting structure 902 discussed above includes the top extending portions 902-1 and the bottom extending portions 902-2. These extending portions may enhance the supporting effect of the supporting structure 902. In some embodiments shown in FIG. 3, the supporting structure 902 is formed without the top extending portions 902-1 and the bottom extending portions 902-2. This simplifies the manufacturing processes of the supporting structure 902 and reduces the cost for forming the supporting structure 902. In some embodiments, the sidewalls of the channel layers 806, the source/drain features 2104, the LDD features 1102 and 2102, the silicide layers 2202, and the source/drain pads 2204 in contact with the supporting structure 902 are aligned in the Z-direction, as shown in FIG. 3. Therefore, a length L of the top extending portions 902-1 and the bottom extending portions 902-2 shown in FIG. 1Z-2 may be in a range from about 0 nm (i.e., no the top extending portions 902-1 and the bottom extending portions 902-2) to about 10 nm.

The embodiments disclosed herein relate to semiconductor structures and their manufacturing methods, and more particularly to methods and semiconductor structures including VGAA transistors with supporting structure(s). Furthermore, the present embodiments provide one or more of the following advantages. The supporting structure is formed before the trimming of the channel layers of the VGAA transistors. Therefore, after the trimming of the channel layers of the VGAA transistors, the supporting structure supports the structures of the VGAA transistors, thereby preventing collapse of the VGAA transistors during the formation of the VGAA transistors.

Thus, one of the embodiments of the present disclosure describes a semiconductor structure that includes a channel layer, a top source/drain feature, a bottom source/drain feature, a gate structure, and a supporting structure. The channel layer extends in a Z-direction. The top source/drain feature is over and electrically connected to the channel layer. The bottom source/drain feature is under and electrically connected to the channel layer. The a gate structure laterally wraps around the channel layer. The supporting structure extends in an X-direction. The supporting structure is in contact with the channel layer, the top source/drain feature, and the bottom source/drain feature in a Y-direction.

In some embodiments, a bottom surface of the top source/drain feature is in contact with the supporting structure.

In some embodiments, the supporting structure further includes a top extending portion vertically between the top source/drain feature and the channel layer.

In some embodiments, the supporting structure further includes a bottom extending portion vertically between the bottom source/drain feature and the channel layer.

In some embodiments, each of the top extending portion and the bottom extending portion has a convex surface from a Y-Z cross-sectional view.

In some embodiments, the gate structure further includes a gate dielectric layer laterally wrapping around the channel layer and a gate electrode layer laterally wrapping around the gate dielectric layer and the channel layer. The gate dielectric layer is in contact with the supporting structure.

In some embodiments, a width of a middle portion of the supporting structure in contact with the channel layer is in a range from about 20 nm to about 100 nm in the Y-direction.

In some embodiments, a top portion of the supporting structure in contact with the top source/drain feature has a width less than the width of the middle portion in the Y-direction.

In some embodiments, the channel layer is asymmetric about the Z-direction from a Y-Z cross-sectional view.

In some embodiments, the supporting structure has a height in a range from about 30 nm to about 150 nm in the Z-direction.

In another of the embodiments, discussed is a semiconductor structure including a channel layer, a supporting structure, a top lightly doped drain (LDD) feature, a top source/drain feature, a bottom LDD feature, a bottom source/drain feature, and a gate structure. The channel layer extends in a Z-direction. The supporting structure extends in an X-direction and is in contact with the channel layer in a Y-direction. The top LDD feature is over and electrically connected to the channel layer and physically attached to the supporting structure. The top source/drain feature is over and electrically connected to the top LDD feature and the channel layer. The bottom LDD feature is under and electrically connected to the channel layer and physically attached to the supporting structure. The bottom source/drain feature is under and electrically connected to the bottom LDD feature and the channel layer. The gate structure laterally wraps around the channel layer.

In some embodiments, the supporting structure is made of a dielectric material. The supporting structure further includes a top extending portion in contact with the top LDD feature and a bottom extending portion in contact with the bottom LDD feature. A portion of the channel layer is vertically between the top extending portion and the bottom extending portion.

In some embodiments, a thickness of the portion of the channel layer is less than a thickness of a portion of the channel layer vertically between the top LDD feature and the bottom LDD feature.

In some embodiments, a bottom surface of the top extending portion is substantially level with a bottom surface of the top LDD feature.

In some embodiments, a bottom surface of the top extending portion is lower than a bottom surface of the top LDD feature.

In some embodiments, a thickness of the bottom extending portion is greater than a thickness of the bottom LDD feature.

In some embodiments, sidewalls of the channel layer, the bottom source/drain feature, the top LDD feature, and the bottom LDD feature in contact with the supporting structure are aligned in the Z-direction.

In yet another of the embodiments, discussed is a method for manufacturing a semiconductor structure that includes forming a semiconductor layer over a substrate, patterning the semiconductor layer to form a channel layer, forming a supporting structure in contact with the channel layer, forming a top source/drain feature over the channel layer and in contact with the supporting structure, forming a gate structure laterally wrapping around the channel layer, and forming a bottom source/drain feature under the channel layer and in contact with the supporting structure.

In some embodiments, the method for manufacturing the semiconductor structure further includes forming a top lightly doped drain (LDD) feature over the channel layer and forming a bottom LDD feature under the channel layer. The top source/drain feature is over the top LDD feature. The bottom source/drain feature is under the bottom LDD feature. The top LDD feature and the bottom LDD feature cover sidewalls of the supporting structure.

In some embodiments, the method for manufacturing the semiconductor structure further includes forming a top spacer over the semiconductor layer, laterally trimming the top spacer and a top portion of the supporting structure, and forming the top source/drain feature between the top spacer and the top portion of the supporting structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a channel layer extending in a Z-direction;
a top source/drain feature over and electrically connected to the channel layer;
a bottom source/drain feature under and electrically connected to the channel layer;
a gate structure laterally wrapping around the channel layer; and
a supporting structure extending in an X-direction, wherein the supporting structure is in contact with the channel layer, the top source/drain feature, and the bottom source/drain feature in a Y-direction.

2. The semiconductor structure as claimed in claim 1, wherein a bottom surface of the top source/drain feature is in contact with the supporting structure.

3. The semiconductor structure as claimed in claim 1, wherein the supporting structure further comprises:
a top extending portion vertically between the top source/drain feature and the channel layer.

4. The semiconductor structure as claimed in claim 3, wherein the supporting structure further comprises:
a bottom extending portion vertically between the bottom source/drain feature and the channel layer.

5. The semiconductor structure as claimed in claim 1, wherein each of the top extending portion and the bottom extending portion has a convex surface from a Y-Z cross-sectional view.

6. The semiconductor structure as claimed in claim 1, wherein the gate structure further comprises:
a gate dielectric layer laterally wrapping around the channel layer; and
a gate electrode layer laterally wrapping around the gate dielectric layer and the channel layer,
wherein the gate dielectric layer is in contact with the supporting structure.

7. The semiconductor structure as claimed in claim 1, wherein a width of a middle portion of the supporting structure in contact with the channel layer is in a range from about 20 nm to about 100 nm in the Y-direction.

8. The semiconductor structure as claimed in claim 1, wherein a top portion of the supporting structure in contact with the top source/drain feature has a width less than the width of the middle portion in the Y-direction.

9. The semiconductor structure as claimed in claim 1, wherein the channel layer is asymmetric about the Z-direction from a Y-Z cross-sectional view.

10. The semiconductor structure as claimed in claim 1, wherein the supporting structure has a height in a range from about 30 nm to about 150 nm in the Z-direction.

11. A semiconductor structure, comprising:
a channel layer extending in a Z-direction;
a supporting structure extending in an X-direction and in contact with the channel layer in a Y-direction;
a top lightly doped drain (LDD) feature over and electrically connected to the channel layer and physically attached to the supporting structure;
a top source/drain feature over and electrically connected to the top LDD feature and the channel layer;
a bottom LDD feature under and electrically connected to the channel layer and physically attached to the supporting structure;
a bottom source/drain feature under and electrically connected to the bottom LDD feature and the channel layer; and
a gate structure laterally wrapping around the channel layer.

12. The semiconductor structure as claimed in claim 11, wherein the supporting structure is made of a dielectric material, the supporting structure further comprises:
a top extending portion in contact with the top LDD feature; and
a bottom extending portion in contact with the bottom LDD feature,
wherein a portion of the channel layer is vertically between the top extending portion and the bottom extending portion.

13. The semiconductor structure as claimed in claim 12, wherein a thickness of the portion of the channel layer is less than a thickness of a portion of the channel layer vertically between the top LDD feature and the bottom LDD feature.

14. The semiconductor structure as claimed in claim 12, wherein a bottom surface of the top extending portion is substantially level with a bottom surface of the top LDD feature.

15. The semiconductor structure as claimed in claim 12, wherein a bottom surface of the top extending portion is lower than a bottom surface of the top LDD feature.

16. The semiconductor structure as claimed in claim 12, wherein a thickness of the bottom extending portion is greater than a thickness of the bottom LDD feature.

17. The semiconductor structure as claimed in claim 11, wherein sidewalls of the channel layer, the bottom source/drain feature, the top LDD feature, and the bottom LDD feature in contact with the supporting structure are aligned in the Z-direction.

18. A method for manufacturing a semiconductor structure, comprising:
forming a semiconductor layer over a substrate;
patterning the semiconductor layer to form a channel layer;
forming a supporting structure in contact with the channel layer;
forming a top source/drain feature over the channel layer and in contact with the supporting structure;
forming a gate structure laterally wrapping around the channel layer; and
forming a bottom source/drain feature under the channel layer and in contact with the supporting structure.

19. The method for manufacturing the semiconductor structure as claimed in claim 18, further comprising:
forming a top lightly doped drain (LDD) feature over the channel layer, wherein the top source/drain feature is over the top LDD feature; and
forming a bottom LDD feature under the channel layer, wherein the bottom source/drain feature is under the bottom LDD feature,
wherein the top LDD feature and the bottom LDD feature cover sidewalls of the supporting structure.

20. The method for manufacturing the semiconductor structure as claimed in claim 18, further comprising:
forming a top spacer over the semiconductor layer;
laterally trimming the top spacer and a top portion of the supporting structure; and
forming the top source/drain feature between the top spacer and the top portion of the supporting structure.
